(19) United States
(12) Patent Application Publication
(10) Pub. No.: US 2026/0150653 A1
(43) Pub. Date: May 28, 2026

(54) INTEGRATED CIRCUIT PACKAGE WITH REDUNDANT CONNECTIVITY

(71) Applicant: TEXAS INSTRUMENTS INCORPORATED, Dallas, TX (US)

(72) Inventors: Jane Qian LIU, Plano, TX (US); Chen DING, Dallas, TX (US); Bradley HASKETT, Magnolia, TX (US)

(21) Appl. No.: 18/963,688

(22) Filed: Nov. 28, 2024

(51) Int. Cl. H01L 23/00; H01L 23/528; H01L 25/065; H01L 25/10

(52) U.S. Cl. CPC H10W 20/435; H10W 72/5445; H10W 72/9445; H10W 90/00; H10W 90/752; H10W 90/754

(57) ABSTRACT

An integrated circuit (IC) package includes: a substrate; a die; first bond wires; and second bond wires. The substrate has terminals including first terminals and second terminals. The second terminals are redundant terminals relative to the first terminals. The die has bond pads including first bond pads and second bond pads. The second bond pads are redundant bond pads relative to the first bond pads. The die includes circuitry and a programmable connectivity interface. The programmable connectivity interface is coupled between the first bond pads and the circuitry. The programmable connectivity interface is coupled between the second bond pads and the circuitry. The first bond wires are coupled between the first terminals and respective bond pads of the first bond pads. The second bond wires are coupled between the second terminals and respective bond pads of the second bond pads.

### BACKGROUND

Some electronic systems include a controller in communication with an integrated circuit (IC) package. The controller and the IC package may include respective terminals for a communication interface and control voltages. Connectivity between the controller and the IC may be interrupted by a broken bond wire or other connectivity issue.

### SUMMARY

In an example, an integrated circuit (IC) package includes: a substrate; a die; first bond wires; and second bond wires. The substrate has terminals including first terminals and second terminals, the second terminals being redundant terminals relative to the first terminals. The die has bond pads including first bond pads and second bond pads, the second bond pads being redundant bond pads relative to the first bond pads, the die including circuitry and a programmable connectivity interface, the programmable connectivity interface coupled between the first bond pads and the circuitry, and the programmable connectivity interface coupled between the second bond pads and the circuitry. The first bond wires are coupled between the first terminals and respective bond pads of the first bond pads. The second bond wires coupled between the second terminals and respective bond pads of the second bond pads.

In another example, an IC includes: bond pads; circuitry; and programmable connectivity interface coupled between the bond pads and the circuitry. The bond pads include first bond pads and second bond pads, the second bond pads redundant relative to the first bond pads. The circuitry is configured to: obtain connectivity test results indicating a connectivity fault preventing communications from another IC via a bond pad of the first bond pads; and update the programmable connectivity interface to enable communications from the other IC via a bond pad of the second bond pads responsive to the connectivity test results.

In yet another example, an apparatus includes: a controller; an IC package coupled to the controller; and a communication interface coupled between the controller and the IC package. The IC package includes: a substrate; a die; first bond wires; and second bond wires. The substrate has terminals including first terminals and second terminals related to the communication interface, the second terminals being redundant terminals relative to the first terminals. The die includes bond pads, circuitry, and a programmable connectivity interface. The bond pads include first bond pads and second bond pads related to the communication interface, the second bond pads being redundant bond pads relative to the first bond pads. The programmable connectivity interface is coupled between the bond pads and the circuitry. The first bond wires are coupled between the first terminals and respective bond pads of the first bond pads. The second bond wires are coupled between the second terminals and respective bond pads of the second bond pads.

### BRIEF DESCRIPTION OF THE DRAWINGS

FIG. 1 is a block diagram of circuitry in accordance with various examples.

FIG. 2 is a diagram of a vehicle in accordance with various examples.

FIG. 3 is a block diagram of a projector in accordance with various examples.

FIG. 4 is a block diagram showing an IC package in accordance with various examples.

FIG. 5 is a block diagram showing a spatial light modulator (SLM) in accordance with various examples.

FIG. 6 is a block diagram of other circuitry in accordance with various examples.

FIG. 7 is a block diagram showing circuitry of an IC package in accordance with various examples.

FIGS. 8 and 9 are flowcharts showing connectivity update methods in accordance with various examples.

### DETAILED DESCRIPTION

The same reference numbers or other reference designators are used in the drawings to designate the same or similar features. Such features may be the same or similar either by function and/or structure.

Described herein are integrated circuit (IC) packages with redundant connectivity. An example IC package includes: a substrate; a die; first bond wires; and second bond wires. The substrate includes first terminals and second terminals, the second terminals of the substrate being redundant terminals relative to the first terminals of the substrate. The die includes first bond pads and second bond pads, the second bond pads of the die being redundant bond pads relative to the first bond pads of the die. The die also includes a programmable connectivity interface, control circuitry, and/or a test interface. The programmable connectivity interface is coupled between the first and second bond pads and the control circuitry and/or the test interface. As used herein, “redundant terminals” of an IC package refer to terminals that are not used unless connectivity tests results indicate other available terminals or related connections have a connectivity fault. As used herein, “redundant bond pads” of a die refer to bond pads that are not used unless connectivity tests results indicate other available bond pads or related connections have a connectivity fault. To use a redundant terminal and a redundant bond pad, a related redundant connection is activated (e.g., externally between IC modules and/or internally within each IC module) to replace a faulty connection. A redundant connection includes at least a redundant terminal, a redundant bond wire, and a redundant bond pad.

During operations, the IC package operates to: obtain data and/or control voltages from a controller or automated test equipment (ATE); and perform target operations responsive to the obtained data and/or control voltages. If there is a connectivity issue, some data and/or some control voltages are not received, which negatively affect the target operations. In some examples, connectivity of the IC package with the controller is tested. If connectivity test results indicate a connectivity fault prevents communications between the controller or ATE and the IC package, the programmable connectivity interface of the IC package is updated.

In some examples, with the updated programmable connectivity interface, communications between a controller and the IC package may use a second terminal and a second bond pad instead of a first terminal and a first bond pad. In some examples, connectivity testing of the IC package is performed by the IC package. In other examples, connectivity testing of the IC package involves test data being transferred from the controller or ATE to the IC package. In some examples, connectivity test results may be used internally within the IC package to update connectivity of IC package circuitry (e.g., control circuitry and/or a test interface) to terminals (e.g., via bonds pads, bond wires, bond fingers, and/or traces) based on the connectivity test results. Connectivity test results may also be transferred from the IC package to the controller or ATE. In such examples, the controller may use the connectivity test result to update connectivity of controller circuitry to terminals (e.g., via bonds pads, bond wires, bond fingers, and/or traces) based on the connectivity test results. In some examples, an ATE may direct an IC package to update connectivity of IC package circuitry to terminals (e.g., via bonds pads, bond wires, bond fingers, and/or traces) based on the connectivity test results.

In some examples, a connectivity test applies a test vector that includes logical “1” for all repairable connections. In other examples, a test vector toggles from a logical “0 ” to a logical “1” to identify faulty conditions including connectivity and “stuck-at” faults (a connection is stuck at a logical “0 ” value). The result of test vector sensing (sometimes referred to as connectivity test results) is a series of logical “1” bits or logical “0 ” bits, where each bit represents a particular connection in order. A logical “1” bit in the connectivity test results indicates a good terminal to bond pad via bond wire connection. A logical “0 ” in the connectivity test results indicates a faulty terminal to bond pad via bond wire connection. In such case, a faulty connection is replaced using an available redundant terminal to bond pad via bond wire connection.

In some examples, connectivity testing and repairs are performed by ATE. For example, the ATE applies test vectors for connectivity tests as part of final IC package or circuitry testing. In some examples, the connectivity test results are read out to the ATE, which may burn the results into FUSE bits of the IC package under test. At the next power up, the faulty connections are replaced with redundant (spare or backup) connections based on the fuse value. In some examples, a counterpart IC chip (e.g., the controllers herein) may read out repair results from a connection repair register (e.g., based on the fuse value) and reorganizes its available connections accordingly.

In some examples, the controller is a first IC package, such as a digital micromirror device (DMD) controller, in communication with a second IC package, such as a DMD. Example components of the DMD include DMD control circuitry and a DMD pixel array. With connectivity testing and related updates, the consistency of DMD operations is improved (i.e., connectivity issues are resolved as needed), reducing the rate of failed IC packages. Such connectivity testing and related update options may be applied to other IC packages (e.g., a power converter IC package, a battery management IC package, an image processor IC package, or other IC packages), where target operations of the IC package are performed responsive to data and/or control voltages from a controller.

An IC package with redundant terminals, redundant bond pads, redundant bond wires, and a programmable connectivity interface enables on-the-fly in-field repair based on connectivity testing results. Such repairs provide advantages including: automation (without customer intervention); simple to implement; and reduction of field return rate and associated costs. Existing controllers do not support such on-the-fly in-field repairs (e.g., pin signal re-assignments). To support such repairs without significant costs, the input/output (I/O) ring of an IC needs sufficient space for redundant terminals, redundant bond pads, and redundant bond wires. In different examples, the ratio of redundant-to regular connections (e.g., terminals, bond pads, and bond wires) may vary. Also, the placement of redundant connections may vary. In some examples, a DMD has many output-only pins. In some examples, to save cost (of changing to bi-directional connections), an IC and related controller can rotate driving-detecting roles during the repair process.

In some examples, redundant connections design and programmable connectivity interface design account for time delay and/or time skew tolerances. In some examples, a programmable connectivity interface includes multiplexers. For an 180 nm process node, a 2:1 multiplexer delay is approximately 50˜70 ps. By using the same multiplexer type for each connection, the net delay is negligible and the skew impact is small and can be ignored. In some examples, redundant connections include a buffer. Such buffering for redundant connections accounts for multiple ending points. In some examples, a distributed buffer structure is used to support a multi-level buffering tree. In some examples, an IC controller accounts for delay due to buffering by providing signals to redundant connections before providing signals regular connections. In some examples, the delay due to additional trace length (e.g., extra trace from a redundant bond pad to a multiplexer of a replaced bond pad) is relatively small and may vary for each replaced connection. To minimize the skew, the number of redundant connections for each regular connection may be limited to a target ratio (e.g., 1 redundant connection for every 2 to 5 regular connection), where each redundant connection is placed as close as possible to the regular connections that may be replaced.

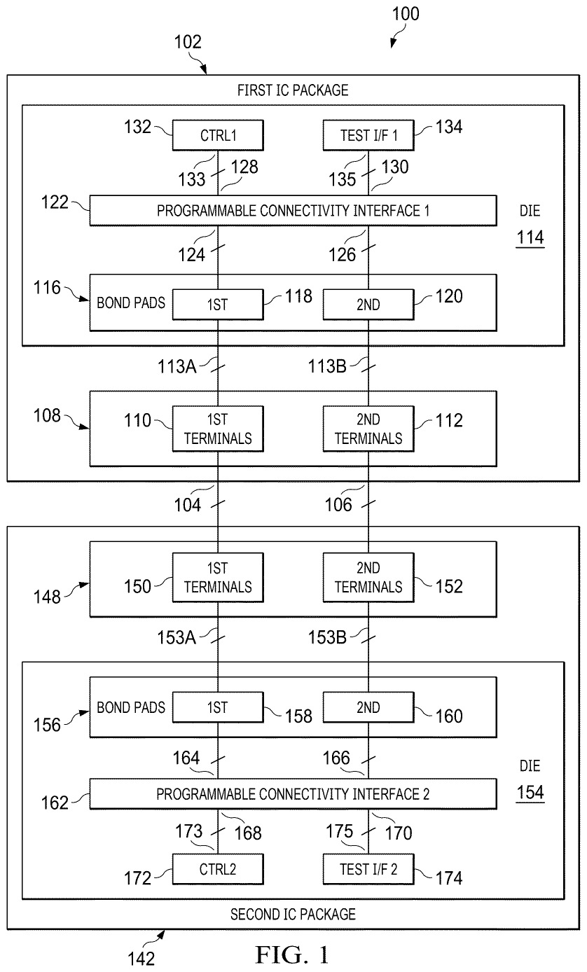

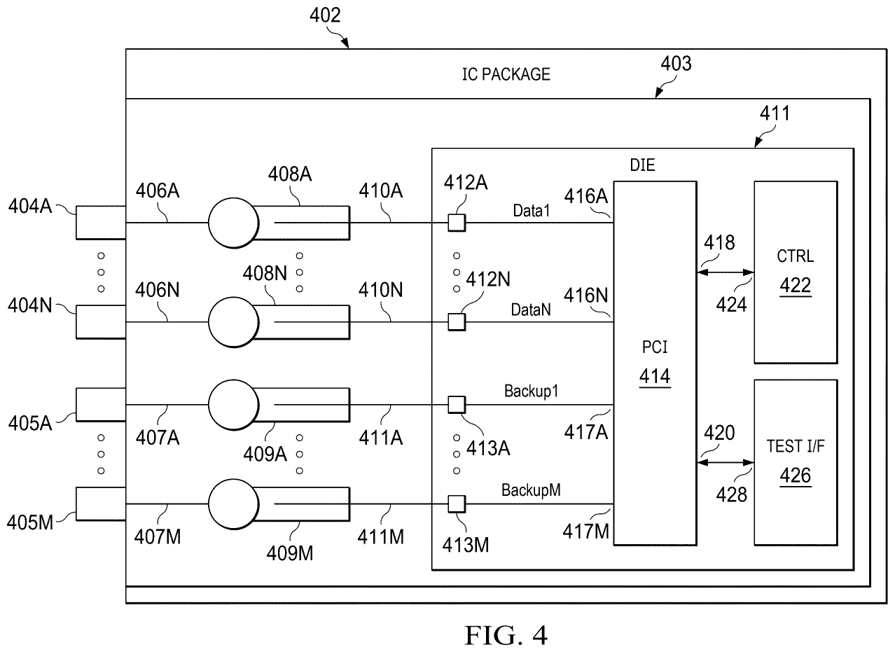

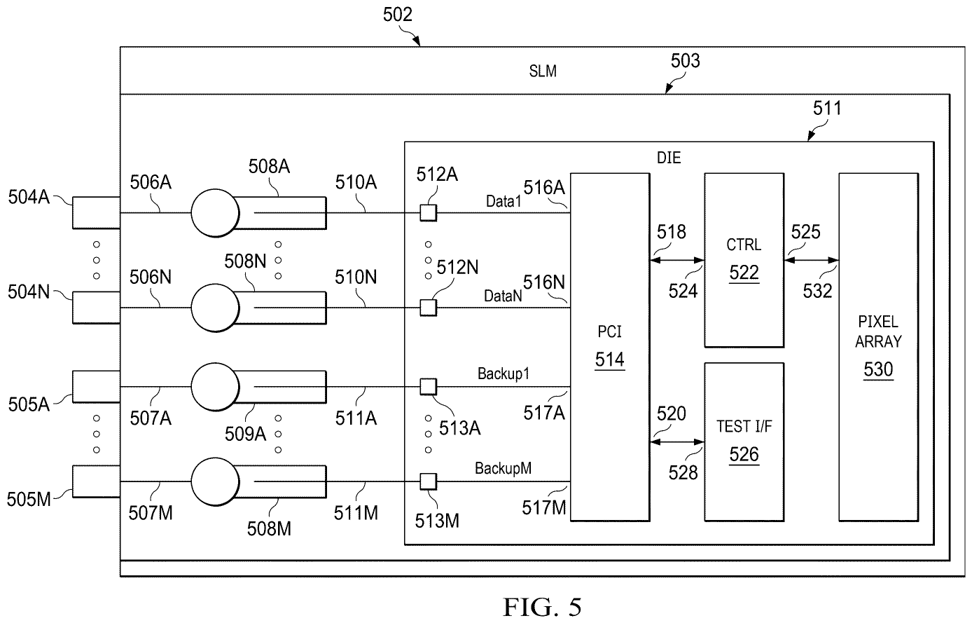

FIG. 1 is a block diagram of circuitry 100 in accordance with various examples. The circuitry 100 includes a first IC package 102 and a second IC package 142. In some examples, the circuitry 100 is part of a display, a projector, a vehicle, a manufacturing environment, a battery management system, a feedback loop, or other electronic system with a controller and related controlled circuitry on separate dies. In the example of FIG. 1, the first IC package 102 includes: a first substrate 108; and a first die 114. In some examples, the first substrate 108 includes or is part of a lead frame that extends underneath the first die 114 and provides a support platform for the first die 114 (see e.g., FIGS. 4 and 5). In FIG. 1, the first substrate 108 includes first terminals 110 and second terminals 112, where the second terminals 112 are redundant terminals relative to the first terminals 110. In some examples, the first terminals 110 and the second terminals 112 are external terminals for the first IC package 102. Example external terminals include, but are not limited to, quad flat no-lead (QFN) terminals, ball grid array (BGA) terminals, and dual-in-line package (DIP) terminals. In such examples, the first die 114 may be coupled to the external terminals (e.g., the first terminals 110 and the second terminals 112) via die bond pads, substrate bond fingers, bond wires between die bond pads and substrate bond fingers, and substrate traces between substrate bond fingers and the external connectors (see e.g., FIGS. 4 and 5).

In the example of FIG. 1, the first die 114 includes bond pads 116; a first programmable connectivity interface 122; first control circuitry 132; and a first test interface 134. The bond pads 116 includes first bond pads 118 and second bond pads 120, where the second bond pads 120 are redundant bond pads relative to the first bond pads 118. The first terminals 110 of the first substrate 108 are coupled to the first bond pads 118 of the first die 114 via first bond wires 113A. The second terminals 112 of the first substrate 108 are coupled to the second bond pads 120 of the first die 114 via second bond wires 113B. The first programmable connectivity interface 122 has first terminals 124, second terminals 126, third terminals 128, and fourth terminals 130. The first control circuitry 132 has terminals 133. The first test interface 134 has terminals 135.

The second IC package 142 includes: a second substrate 148; and a second die 154. In some examples, the second substrate 148 includes or is part of a lead frame that extends underneath the second die 154 provides a support platform for the second die 154 (see e.g., FIGS. 4 and 5). In FIG. 1, the second substrate 148 includes first terminals 150 and second terminals 152, where the second terminals 152 are redundant terminals relative to the first terminals 150. In some examples, the first terminals 150 and the second terminals 152 are external connectors for the second IC package 142. In such examples, the second die 154 may be coupled to the external terminals (e.g., the first terminals 150 and the second terminals 152) via die bond pads, substrate bond fingers, bond wires between die bond pads and substrate bond fingers, and substrate traces between substrate bond fingers and the external connectors (see e.g., FIGS. 4 and 5).

The second die 154 includes bond pads 156; a second programmable connectivity interface 162; second control circuitry 172; and a second test interface 174. The bond pads 156 include first bond pads 158 and second bond pads 160, where the second bond pads 160 are redundant bond pads relative to the first bond pads 158. The first terminals 150 of the second substrate 148 are coupled to the first bond pads 158 of the second die 154 via first bond wires 153A. The second terminals 152 of the second substrate 148 are coupled to the second bond pads 160 of the first die 114 via second bond wires 153B. The second programmable connectivity interface 162 has first terminals 164, second terminals 166, third terminals 168, and fourth terminals 170. The second control circuitry 172 has terminals 173. The second test interface 174 has terminal 175.

In the example of FIG. 1, each of the terminals 133 of the first control circuitry 132 is coupled to a respective terminal of the third terminals 128 of the first programmable connectivity interface 122. Each of the terminals 135 of the first test interface 134 is coupled to a respective terminal of the fourth terminals 130 of the first programmable connectivity interface 122. Each of the first terminals 124 of the first programmable connectivity interface 122 is coupled to a respective bond pad of the first bond pads 118. Each of the first bond pads 118 is coupled to a respective terminal of the first terminals 110 via bond wires of the first bond wires 113A. Each of the second terminals 126 of the first programmable connectivity interface 122 is coupled to a respective bond pad of the second bond pads 120 of the first IC package 102. Each of the second bonds pads 120 is coupled to a respective terminal of the second terminals 112 of the first IC package 102 via bond wires of the second bond wires 113B.

Each of the first terminals 110 of the first IC package 102 is coupled to a respective terminal of the first terminals 150 of the second IC package 142 via first communication interface lines 104. Each of the first terminals 150 is coupled to a respective bond pad of the first bond pads 158 via bond wires of the first bond wires 153A. Each of the first bond pads 158 is coupled to a respective terminal of the first terminals 164 of the second programmable connectivity interface 162. Each of the second terminals 112 of the first IC package 102 is coupled to a respective terminal of the second terminals 152 of the second IC package 142 via second communication interface lines 106. Each of the second terminals 152 is coupled to a respective bond pad of the second bond pads 160. Each of the first terminals 150 is coupled to a respective bond pad of the first bond pads 158 via bond wires of the second bond wires 153B. Each of the second bond pads 160 is coupled to a respective terminal of the second terminals 166 of the second programmable connectivity interface 162. Each of the third terminals 168 of the second programmable connectivity interface 162 is coupled to a respective terminal of the terminals 173 of the second control circuitry 172. Each of the fourth terminals 170 of the second programmable connectivity interface 162 is coupled to a respective terminal of the terminals 175 of the second test interface 174.

In some examples, the circuitry 100 performs connectivity test operations. In an example connectivity test, the first test interface 134 provides test data to the second test interface 174 via the first programmable connectivity interface 122, the first bond pads 118 of the first IC package 102, the first bond wires 113A of the first IC package 102, the first terminals 110 of the first IC package 102, the first communication interface lines 104, the first terminals 150 of the second IC package 142, the first bond wires of the second IC package 142, the first bond pads 118 of the second IC package 142, and the first terminals 164 of the second programmable connectivity interface 162. The second test interface 174 analyzes the test data to determine connectivity test results. In some examples, a successful connectivity test indicates the test data from the first test interface 134 is received at the second test interface 174. The test data includes, for example, a single bit value (e.g., a logical “1”) or a multi-bit value (e.g., with at least one logical “1”) for each connection between the and the first test interface 134 and the second test interface 174.

An example first connection between the first test interface 134 and the second test interface 174 includes: a first of the terminals 135 of the first test interface 134; a first of the fourth terminals 130 of the first programmable connectivity interface 122; a first of the first terminals 124 of the first programmable connectivity interface 122; a first of the first bond pads 118; a first of the first bond wires 113A; a first of the first communication interface lines 104; a first of the first terminals 150; a first of the first bond wires 153A; a first of the first bond pads 158; a first of the first terminals 164 of the second programmable connectivity interface 162; a first of the fourth terminals 170 of the second programmable connectivity interface 162; and a first of the terminals 173 of the second control circuitry 172. An example second connection between the first test interface 134 and the second test interface 174 includes: a second of the terminals 135 of the first test interface 134; a second of the fourth terminals 130 of the first programmable connectivity interface 122; a second of the first terminals 124 of the first programmable connectivity interface 122; a second of the first bond pads 118; a second of the first bond wires 113A; a second of the first communication interface lines 104; a second of the first terminals 150; a second of the first bond wires 153A; a second of the first bond pads 158; a second of the first terminals 164 of the second programmable connectivity interface 162; a second of the fourth terminals 170 of the second programmable connectivity interface 162; and a second of the terminals 173 of the second control circuitry 172.

If there is a connectivity fault, the second test interface 174 does not receive all test data correctly. In such case, the connectivity test results indicate which connection (or connections) between the first test interface 134 and the second test interface 174 is faulty. To replace a faulty connection with a redundant connection, the programming of first programmable connectivity interface 122 and of the second programmable connectivity interface 162 are updated. If desired, the redundant connection replacing the faulty connection may be tested. After any faulty connections are replaced with redundant connections, the first control circuitry 132 of the first IC package 102 transmits control data to the second control circuitry 172 of the second IC package 142 using the programmed connections. The second control circuitry 172 uses the control data to perform target operations of the second IC package 142.

In one example, the first IC package 102 is a spatial light modulator (SLM) controller, and the second IC package 142 is an SLM. In such examples, the control data transmitted from the first IC package 102 to the second IC package 142 may include control voltages, bit plane data, bit data (not in bit planes), and configuration data. In response to the bit plane data and the configuration data, the second control circuitry 172 directs the second IC package 142 to control an array of micromirrors responsive to the bit plane data and the configuration data. In some examples, connectivity testing of the second IC package 142 is performed by ATE instead of the first IC package 102.

Using redundant terminals (e.g., the second terminals 112 of the first IC package 102, or the second terminals 152 of the second IC package 142 in FIG. 1), redundant bond pads (e.g., the second bond pads 120 of the first die 114, or the second bond pads 160 of the second die 154 in FIG. 1), redundant bond wires (e.g., the second bond wires 113B of the first IC package 102, or the second bond wires 153B of the second IC package 142 in FIG. 1), test interfaces (e.g., the first test interface 134 of the first IC package 102, or the second test interface 174 of the second IC package 142 in FIG. 1), and programmable connectivity interfaces (e.g., first programmable connectivity interface 122 of the first IC package 102, or the second programmable connectivity interface 162 of the second IC package 142 in FIG. 1), the first IC package 102 and the second IC package 142 of FIG. 1 enable on-the-fly in-field repair based on connectivity testing results. Such repairs provide advantages including: automation (without customer intervention); simple to implement; and reduction of field return rate and associated costs. To support such repairs without significant costs, an I/O ring of an IC package has sufficient space for redundant terminals, redundant bond pads, and redundant bond wires. In different examples, the ratio of redundant-to regular connections (e.g., terminals, bond pads, and bond wires) may vary. Also, the placement of redundant connections may vary. In some examples, an IC package has many output-only pins. In some examples, to save cost (of changing to bi-directional connections), an IC and related controller can rotate driving-detecting roles during the repair process.

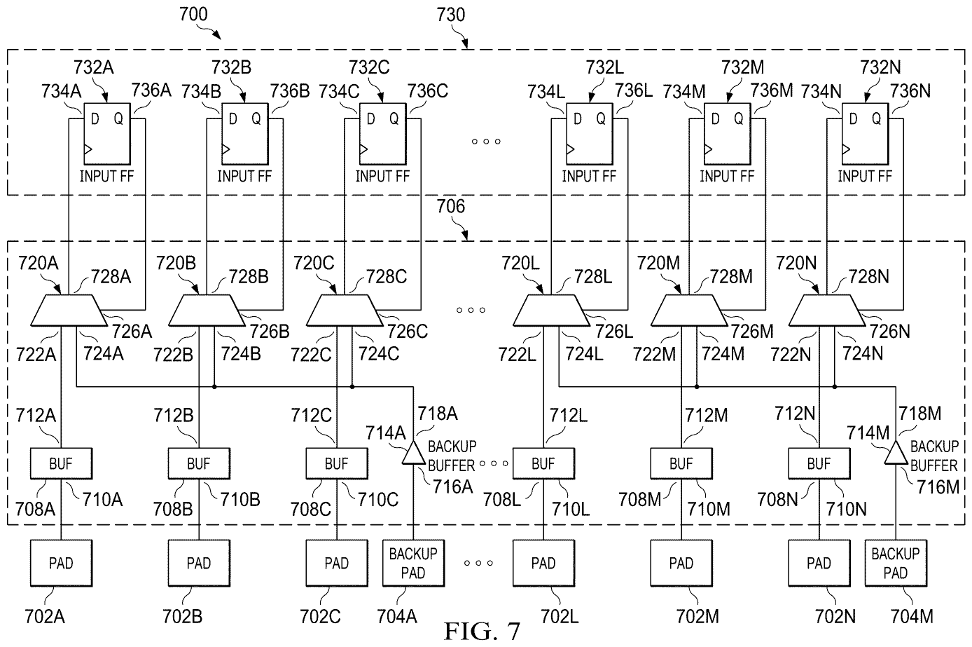

In some examples, redundant connections design and programmable connectivity interface design account for time delay and/or time skew tolerances. In some examples, a programmable connectivity interface includes multiplexers, buffers, and storage (see e.g., FIG. 7). By using the same multiplexer type for each connection, the net delay is negligible and the skew impact is small and can be ignored. The buffers for redundant connections account for multiple ending points. In some examples, a distributed buffer structure is used to support a multi-level buffering tree. In some examples, an IC controller accounts for delay due to buffering by providing signals to redundant connections before providing signals regular connections. In some examples, the delay due to additional trace length (e.g., extra trace from a redundant bond pad to a multiplexer of a replaced bond pad) is relatively small and may vary for each replaced connection. To minimize the skew, the number of redundant connections for each regular connection may be limited to a target ratio (e.g., 1 redundant connection for every 2 to 5 regular connection), where each redundant connection is placed as close as possible to the regular connections that may be replaced.

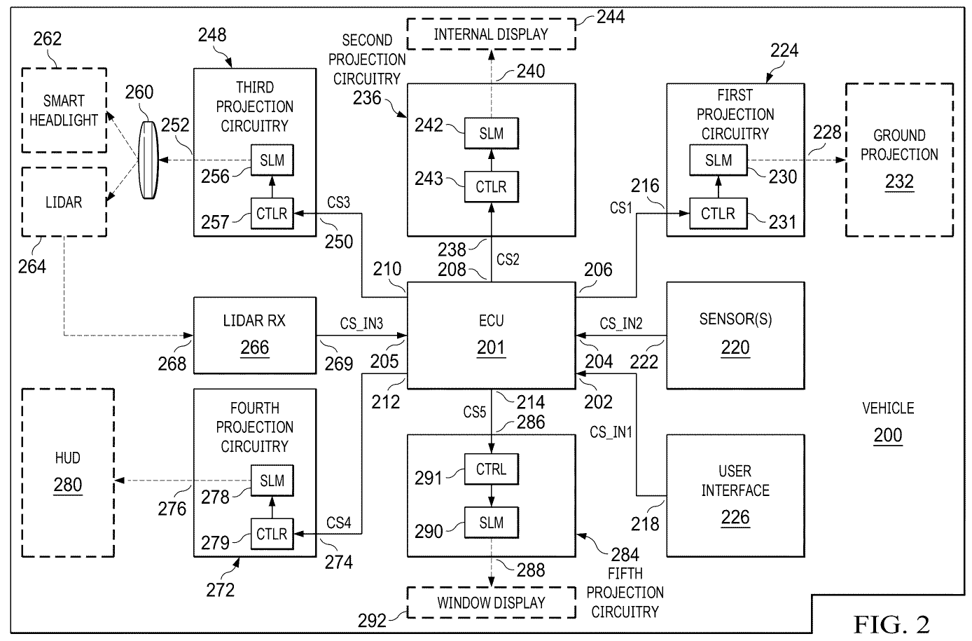

FIG. 2 is a diagram of a vehicle in accordance with various examples. The vehicle 200 may be a land-based vehicle (e.g., a car or truck), a water-based vehicle (e.g., a boat), or an air-based vehicle (e.g., an airplane). As shown, the vehicle 200 includes an electronic control unit (ECU) 201, first projection circuitry 224, second projection circuitry 236, third projection circuitry 248, optics 260, a light detection and ranging (LIDAR) receiver (RX) 266, fourth projection circuitry 272, fifth projection circuitry 284, sensor(s) 220, and a user interface 216. Each of the first projection circuitry 224, second projection circuitry 236, third projection circuitry 248, fourth projection circuitry 272, and fifth projection circuitry 284 includes circuitry corresponding to the circuitry 100 of FIG. 1. The ECU 201 has a first terminal 202, a second terminal 204, a third terminal 205, a fourth terminal 206, a fifth terminal 208, a sixth terminal 210, a seventh terminal 212, and an eighth terminal 214. The LIDAR RX 266 has an optical input 268 and a terminal 269. In some examples, the LIDAR RX 266 is part of the SLM 256. In other words, the SLM 256 may be in the transmitting path, the receiving path, or both paths for LIDAR operations. In some examples, the LIDAR RX 266 may be part of a different SLM (e.g., the transmitting path and the receiving paths are separate). The sensor(s) 220 has a terminal 222. The user interface 226 has a terminal 218.

In the example of FIG. 2, the first projection circuitry 224 has a terminal 226 and an optical output 228. The first projection circuitry 224 includes a first SLM 230 and a first controller 231. The first controller 231 and the first SLM 230, respectively, are examples of the first IC package 102 and the second IC package 142 in FIG. 1. The second projection circuitry 236 has a terminal 238 and an optical output 240. The second projection circuitry 236 includes a second SLM 242 and a second controller 243. The second controller 243 and the second SLM 242, respectively, are examples of the first IC package 102 and the second IC package 142 in FIG. 1. The third projection circuitry 248 has a terminal 250 and an optical output 252. In some examples, the optics 260 directs light from the optical output 252 of the third projection circuitry 248 to a smart headlight projection 262 or a LIDAR projection 264. The LIDAR RX 266 receives LIDAR results at the optical input 268 and provides third input control signals (CS_IN3) at the terminal 269 responsive to the LIDAR results. The third projection circuitry 248 includes a third SLM 256 and a third controller 257. The third controller 257 and the third SLM 256, respectively, are examples of the first IC package 102 and the second IC package 142 in FIG. 1. The fourth projection circuitry 272 has a terminal 274 and an optical output 276. The fourth projection circuitry 272 includes a fourth SLM 278 and a fourth controller 279. The fourth controller 279 and the fourth SLM 278, respectively, are examples of the first IC package 102 and the second IC package 142 in FIG. 1. The fifth projection circuitry 284 has a terminal 286 and an optical output 288. The fifth projection circuitry 284 includes a fifth SLM 290 and a fifth controller 291. The fifth controller 291 and the fifth SLM 290, respectively, are examples of the first IC package 102 and the second IC package 142 in FIG. 1.

In the example of FIG. 2, the first terminal 202 of the ECU 201 is coupled to the terminal 218 of the user interface 216. The second terminal 204 of the ECU 201 is coupled to the terminal 222 of the sensor(s) 220. The third terminal 205 of the ECU 201 is coupled to the terminal 269 of the LIDAR RX 266. The fourth terminal 206 of the ECU 201 is coupled to the terminal 226 of the first projection circuitry 224. The fifth terminal 208 of the ECU 201 is coupled to the terminal 238 of the second projection circuitry 236. The sixth terminal 210 of the ECU 201 is coupled to the terminal 250 of the third projection circuitry 248. The seventh terminal 212 of the ECU 201 is coupled to the terminal 274 of the fourth projection circuitry 272. The eighth terminal 214 of the ECU 201 is coupled to the terminal 286 of the fifth projection circuitry 284.

In some examples, the ECU 201 is configured to: receive first input control signals (CS_IN1) from the user interface 216 at the first terminal 202; receive second input control signals (CS_IN2) from the sensor(s) 220 at the second terminal 204; receive CS_IN3 from the LIDAR RX 266 at the third terminal 205; provide first control signals (CS1) at the fourth terminal 206 responsive to CS_IN1, CS_IN2, and/or ground projection control operations of the ECU 201; provide second control signals (CS2) at the fifth terminal 208 responsive to CS_IN1, CS_IN2, and/or internal display control operations of the ECU 201; provide third control signals (CS3) at the sixth terminal 210 responsive to CS_IN1, CS_IN2, smart headlight control operations of the ECU 201, and/or light detection and ranging (LIDAR) control operations of the ECU 201; provide fourth control signals (CS4) at the seventh terminal 212 responsive to CS_IN1, CS_IN2, and/or head-up display control operations of the ECU 201; provide fifth control signals (CS5) at the eighth terminal 214 responsive to CS_IN1, CS_IN2, and/or window display control operations of the ECU 201.

In some examples, the first projection circuitry 224 operates to provide a ground projection 232 via the optical output 228 responsive to CS1 and operations of the first SLM 230. The second projection circuitry 236 operates to provide an internal display projection 244 via the optical output 240 responsive to CS2 and operations of the second SLM 242. The third projection circuitry 248 operates to provide the smart headlight projection 262 or the LIDAR projection 264 via the optical output 252 and the optics 260 responsive to CS3 and operations of the third SLM 256. The fourth projection circuitry 272 operates to provide a heads-up display (HUD) projection 280 via the optical output 276 responsive to CS4 and operations of the fourth SLM 278. The fifth projection circuitry 284 operates to provide a window display projection 292 via the optical output 288 responsive to CS5 and operations of the fifth SLM 290.

In some examples, the first projection circuitry 224, the second projection circuitry 236, the third projection circuitry 248, the fourth projection circuitry 272, and the fifth projection circuitry 284 support different projection resolutions and/or brightness levels. In different examples, the vehicle 200 may omit one or more of the first projection circuitry 224, the second projection circuitry 236, the third projection circuitry 248, the fourth projection circuitry 272, and the fifth projection circuitry 284. In some examples, different projections options may be supported by a single projection circuit. For example, the third projection circuitry 248 of FIG. 2 supports a smart headlight projection 262 and a LIDAR projection 264. In other examples, the smart headlight projection 262 and the LIDAR projection 264 may be supported by different projection circuitry. Also, it may be possible to support other combinations of projections with one projection circuitry. In different examples, the first SLM 230, the second SLM 242, the third SLM 256, the fourth SLM 278, and the fifth SLM 290 may support the same projection resolution or different projection resolutions.

In some examples, each controller and respective SLM of FIG. 2 (e.g., the first controller 231 and the first SLM 230, the second controller 243 and the second SLM 242, and so on) performs the connectivity test operations described in FIG. 1. If there is a connectivity fault, the connectivity test results indicate which connection (or connections) is faulty and a redundant connection is used to replace the faulty connection. After any faulty connections are replaced with redundant connections, each controller and respective SLM of FIG. 2 performs target operations (e.g., smart headlight operations, LIDAR operations, HUD operations, etc.).

Using redundant terminals (e.g., the second terminals 112 of the first IC package 102, or the second terminals 152 of the second IC package 142 in FIG. 1), redundant bond pads (e.g., the second bond pads 120 of the first die 114, or the second bond pads 160 of the second die 154 in FIG. 1), redundant bond wires (e.g., the second bond wires 113B of the first IC package 102, or the second bond wires 153B of the second IC package 142 in FIG. 1), test interfaces (e.g., the first test interface 134 of the first IC package 102, or the second test interface 174 of the second IC package 142 in FIG. 1), and programmable connectivity interfaces (e.g., first programmable connectivity interface 122 of the first IC package 102, or the second programmable connectivity interface 162 of the second IC package 142 in FIG. 1), each SLM and SLM controller pair in FIG. 2 enables on-the-fly in-field repair based on connectivity testing results. Such repairs provide advantages including: automation (without customer intervention); simple to implement; and reduction of field return rate and associated costs. To support such repairs without significant costs, the I/O ring of an SLM and/or an SLM controller has sufficient space for redundant terminals, redundant bond pads, and redundant bond wires. In different examples, the ratio of redundant-to regular connections (e.g., terminals, bond pads, and bond wires) may vary. Also, the placement of redundant connections may vary. In some examples, an SLM or SLM controller has many output-only pins. In some examples, to save cost (of changing to bi-directional connections), an SLM and related SLM controller can rotate driving-detecting roles during the repair process.

In some examples, redundant connections design and programmable connectivity interface design account for time delay and/or time skew tolerances. In some examples, a programmable connectivity interface includes multiplexers, buffers, and storage (see e.g., FIG. 7). By using the same multiplexer type for each connection, the net delay is negligible and the skew impact is small and can be ignored. The buffers for redundant connections account for multiple ending points. In some examples, a distributed buffer structure is used to support a multi-level buffering tree. In some examples, an SLM controller accounts for delay due to buffering by providing signals to redundant connections before providing signals regular connections. In some examples, the delay due to additional trace length (e.g., extra trace from a redundant bond pad to a multiplexer of a replaced bond pad) is relatively small and may vary for each replaced connection. To minimize the skew, the number of redundant connections for each regular connection may be limited to a target ratio (e.g., 1 redundant connection for every 2 to 5 regular connection), where each redundant connection is placed as close as possible to the regular connections that may be replaced.

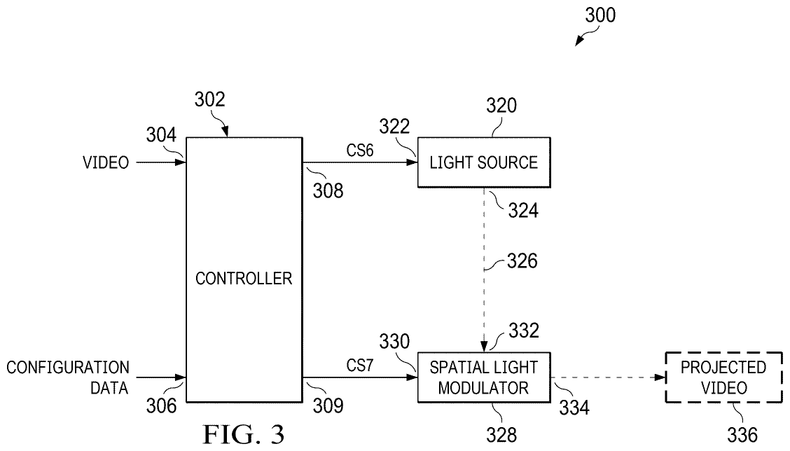

FIG. 3 is a block diagram of a projector 300 in accordance with various examples. The projector 300 is, for example a traditional projector, an augmented reality (AR) display, a virtual reality (VR) display, a smart headlight, a heads-up display (HUD), an automotive ground projector, a light detection and ranging (LIDAR) unit, a lithography unit, a three-dimensional (3D) printer, a spectroscopy display, a 3D display, or another type of projector. The circuitry 100 may also represent some or all of a display such as a DMD display.

As shown, the projector 300 includes a controller 302, a light source 320, and an SLM 328. The controller 302 is an example of the first IC package 102 in FIG. 1. The SLM 328 is an example of the second IC package 142 in FIG. 1. The controller 302 has a first terminal 304, a second terminal 306, a third terminal 308, and a fourth terminal 309. The light source 320 has an input 322 and an optical output 324. The SLM 328 has an input 330, an optical input 332, and an optical output 334. In the example of FIG. 3, the SLM 328. In different examples, the SLM 328 may perform spatial modulation of light using mechanical, electro-optical, thermo-optical, and/or magneto-optical control options.

In the example of FIG. 3, the controller 302 operates to: receive video data at the first terminal 304; receive configuration data at the second terminal 306; provide control signals CS6 at the third terminal 308 responsive to the video data and the configuration data; and provide control signals CS7 at the fourth terminal 309 responsive to the video and the configuration data. The light source 320 operates to: receive the control signals CS6 at the input 322; and generate light 326 at the optical output 324 responsive to the control signal CS6. In some examples, the light source 320 modulates the intensity, color, and/or timing of the light 326 at the optical output 324 responsive to the control signals CS6. The SLM 328 operates to: receive the control signals CS7 at the input 330; receive the light 326 at the optical input 332; and provide spatially-modulated light at the optical output 334 responsive to the light 326 and the control signals CS7. In some examples, the control signals CS7 include control voltages, bit plane data, bit data (not in plane data), and configuration signals to control light modulation options of the SLM 328. Without limitation, the control signals CS7 may be transferred to the SLM 328 using low-voltage differential signaling (LVDS), dedicated inputs/outputs, programmable inputs/outputs, a dedicated communication interface, or a programmable communication interface. The spatially-modulated light from the SLM 328 results in projected video 336.

In some examples, the controller 302 and the SLM 328 perform the connectivity test operations described in FIG. 1. If there is a connectivity fault, the connectivity test results indicate which connection (or connections) is faulty and a redundant connection is used to replace the faulty connection. After any faulty connections are replaced with redundant connections, the controller 302 and the SLM 328 perform target operations to provide the projected video 336.

FIG. 4 is a block diagram showing an IC package 402 in accordance with various examples. The IC package 402 is an example of the first IC package 102 or the second IC package 142 of FIG. 1. As shown, the IC package 402 has a substrate 403, first bond wires 410A to 401N, second bond wires 411A to 411M, and a die 411. In some examples, the substrate 403 includes or is part of a lead frame, and the die 411 is on the substrate 403. The substrate 403 includes first terminals 404A to 404N, second terminals 405A to 405N, first traces 406A to 406N, second traces 407A to 407M, first bond fingers 408A to 408N, and second bond fingers 409A to 409M. The first terminals 404A to 404N are examples of the first terminals 110 of the first IC package 102 or the first terminals 150 of the second IC package 142 in FIG. 1. The second terminals 405A to 405M are examples of the second terminals 112 of the first IC package 102 or the second terminals 152 of the second IC package 142 in FIG. 1. The first bond wires 410A to 410N are examples of the first bond wires 113A of the first IC package 102 or the first bond wires 153A of the second IC package 142 in FIG. 1. The second bond wires 411A to 411M are examples of the second bond wires 113B of the first IC package 102 or the second bond wires 153B of the second IC package 142 in FIG. 1.

The die 411 is an example of the first die 114 or the second die 154 in FIG. 1. In the example of FIG. 4, the die 411 includes first bond pads 412A to 412N, second bond pads 413A to 413M, a programmable connectivity interface (PCI) 414, control circuitry 422, and a test interface 426. The first bond pads 412A to 412N are examples of the first bond pads 118 of the first IC package 102 or the first bond pads 158 of the second IC package 142 in FIG. 1. The second bond pads 413A to 413M are examples of the second bond pads 120 of the first IC package 102 or the second bond pads 160 of the second IC package 142 in FIG. 1. The programmable connectivity interface 414 is an example of the first programmable connectivity interface 122 of the first IC package 102 or the second programmable connectivity interface 162 of the second IC package 142 in FIG. 1. The control circuitry 422 is an example of the first control circuitry 132 of the first IC package 102 or the second control circuitry 172 of the second IC package 142 in FIG. 1. The test interface 426 is an example of the first test interface 134 of the first IC package 102 or the second test interface 174 of the second IC package 142 in FIG. 1.

In the example of FIG. 4, the programmable connectivity interface 414 has first terminals 416A to 416N, second terminals 417A to 417M, third terminals 418, and fourth terminals 420. The first terminals 416A to 416N are examples of the first terminals 124 of the first programmable connectivity interface 122 or the first terminals 164 of the second programmable connectivity interface 162 in FIG. 1. The second terminals 417A to 417M are examples of the second terminals 126 of the first programmable connectivity interface 122 or the second terminals 166 of the second programmable connectivity interface 162 in FIG. 1. The third terminals 418 are examples of the third terminals 128 of the first programmable connectivity interface 122 or the third terminals 168 of the second programmable connectivity interface 162 in FIG. 1. The fourth terminals 420 are examples of the fourth terminals 130 of the first programmable connectivity interface 122 or the fourth terminals 170 of the second programmable connectivity interface 162 in FIG. 1.

In the example of FIG. 4, the control circuitry 422 has terminals 424 and the test interface 426 has terminals 428. The terminals 424 of the control circuitry 422 are examples of the terminals 173 of the second control circuitry 172 in FIG. 1. The terminals 428 of the test interface 426 are examples of the terminals 175 of the second test interface 174 in FIG. 1.

In the example of FIG. 4, the first terminals 404A to 404N are coupled to respective ones of the first bond fingers 408A to 408N via the first traces 406A to 406N of the substrate 403. The first bond fingers 408A to 408N are coupled to respective ones of the first bond pads 412A to 412N of the die 411 via the first bond wires 410A to 410N. The first bond pads 412A to 412N are coupled to respective ones of the first terminals 416A to 416N of the programmable connectivity interface 414 via traces Data1 to DataN of the die 411. The second terminals 405A to 405M are coupled to respective ones of the second bond fingers 409A to 409M via the second traces 407A to 407M of the substrate 403. The second bond fingers 409A to 409M are coupled to respective ones of the second bond pads 413A to 413M of the die 411 via the second bond wires 411A to 411M. The second bond pads 413A to 413M are coupled to respective ones of the second terminals 417A to 417M of the programmable connectivity interface 414 via traces Backup1 to BackupM of the die 411. The third terminals 418 of the programmable connectivity interface 414 are coupled to the terminals 424 of the control circuitry 422. The fourth terminals 420 of the programmable connectivity interface 414 are coupled to the terminals 428 of the test interface 426. The connection between the control circuitry 422 and the test interface 426 may be direct (not shown) or may be through the programmable connectivity interface 414.

In some examples, the IC package 402 is an SLM controller, a battery management system (BMS) controller, a sensor controller, power converter controller, or other controller. In such examples, the control circuitry 422 operates to: initiate connectivity test operations; and perform target controller operations. Example connectivity test operations include providing test data to the test interface 426; directing the test interface 426 to begin providing test data; receiving connectivity test results; and directing the programmable connectivity interface 414 to update a faulty connection with an available redundant connection. An example replacement operation may replace a faulty connection that includes the first terminal 404A, the first trace 406A, the first bond finger 408A, the first bond wire 410A, the first bond pad 412A, and the Data1 trace with a redundant connection that includes the second terminal 405A, the second trace 407A, the second bond finger 409A, the second bond wire 411A, the second bond pad 413A, and the Backup1 trace. In some examples, the IC package 402 supports N data connections and M backup connections, where N is greater than M. Once faulty connections are replaced with redundant connections, the control circuitry 422 performs the target controller operations. Example target controller operations include providing commands, data, and/or configuration data to another IC package. In response, the other IC package performs SLM operations, a battery management operations, sensor operations, power converter operations, or other operations. In some examples, the operations and circuitry of the control circuitry 422 and the test interface 426 are combined.

In some examples, the IC package 402 is an SLM. In such examples, the control circuitry 422 operates to: perform connectivity test operations; and perform target SLM operations. Example connectivity test operations include directing the test interface 426 to receive test data from an SLM controller; obtaining connectivity test results responsive to the test data; directing the programmable connectivity interface 414 to update a faulty connection with an available redundant connection; and transmitting the connectivity test results to an SLM controller. An example replacement operation may replace a faulty connection that includes the first terminal 404A, the first trace 406A, the first bond finger 408A, the first bond wire 410A, the first bond pad 412A, and the Data1 trace with a redundant connection that includes the second terminal 405A, the second trace 407A, the second bond finger 409A, the second bond wire 411A, the second bond pad 413A, and the Backup1 trace. In some examples, the IC package 402 supports N data connections and M backup connections, where N is greater than M. Once faulty connections are replaced with redundant connections, the control circuitry 422 is able to perform target SLM operations. Example target SLM operations include: receiving bit plane data and/or configuration data from an SLM controller; and controlling micromirrors responsive to the bit plane data and/or configuration data. In some examples, the operations and circuitry of the control circuitry 422 and the test interface 426 are combined.

In the example of FIG. 4, the first terminals 404A to 404N, the second terminals 405A to 405M, the first bond fingers 408A to 408N, the second bond fingers 409A to 409M, the first bond wires 410A to 410N, the second bond wires 411A to 411M, the first bond pads 412A to 412N, the second bond pads 413A to 413M are represented on the left side of the IC package 402. In other examples, the first terminals 404A to 404N, the second terminals 405A to 405M, the first bond fingers 408A to 408N, the second bond fingers 409A to 409M, the first bond wires 410A to 410N, the second bond wires 411A to 411M, the first bond pads 412A to 412N, the second bond pads 413A to 413M may be: on any one side of the IC package 402; distributed on two sides of the IC package 402; distributed on three sides of the IC package 402; or distributed on four sides of the IC package. In different examples, the first terminals 404A to 404N and the second terminals 405A to 405M may be QFN terminals, BGA terminals, DIP terminals, or other external terminal types.

Using redundant terminals (e.g., the second terminals 405A to 405M in FIG. 4, or the second terminals 152 of the second IC package 142 in FIG. 1), redundant bond pads (e.g., the second bond pads 413A to 413M in FIG. 4, or the second bond pads 160 of the second die 154 in FIG. 1), redundant bond wires (e.g., the second bond wires 411A to 411M in FIG. 4, or the second bond wires 153B of the second IC package 142 in FIG. 1), a test interface (e.g., the test interface 426 in FIG. 4, or the second test interface 174 in FIG. 1), and a programmable connectivity interface (e.g., the programmable connectivity interface 414 in FIG. 4, or the second programmable connectivity interface 162 in FIG. 1), the IC package 402 enables on-the-fly in-field repair based on connectivity testing results. Such repairs provide advantages including: automation (without customer intervention); simple to implement; and reduction of field return rate and associated costs. To support such repairs without significant costs, an I/O ring of the IC package 402 has sufficient space for redundant terminals, redundant bond pads, and redundant bond wires. In different examples, the ratio of redundant-to regular connections (e.g., terminals, bond pads, and bond wires) may vary. Also, the placement of redundant connections may vary. In some examples, an SLM or SLM controller has many output-only pins. In some examples, to save cost (of changing to bi-directional connections), an SLM and related SLM controller can rotate driving-detecting roles during the repair process.

In some examples, redundant connections design and programmable connectivity interface design account for time delay and/or time skew tolerances. In some examples, a programmable connectivity interface includes multiplexers, buffers, and storage (see e.g., FIG. 7). By using the same multiplexer type for each connection, the net delay is negligible and the skew impact is small and can be ignored. The buffers for redundant connections account for multiple ending points. In some examples, a distributed buffer structure is used to support a multi-level buffering tree. In some examples, an SLM controller accounts for delay due to buffering by providing signals to redundant connections before providing signals regular connections. In some examples, the delay due to additional trace length (e.g., extra trace from a redundant bond pad to a multiplexer of a replaced bond pad) is relatively small and may vary for each replaced connection. To minimize the skew, the number of redundant connections for each regular connection may be limited to a target ratio (e.g., 1 redundant connection for every 2 to 5 regular connection), where each redundant connection is placed as close as possible to the regular connections that may be replaced.

FIG. 5 is a block diagram showing a SLM 502 in accordance with various examples. The SLM 502 is an example of the second IC package 142 in FIG. 1, any of the first SLM 230, the second SLM 242, the third SLM 256, the fourth SLM 278, and the fifth SLM 290 in FIG. 2, the SLM 328 in FIG. 3, or the IC package 402 in FIG. 4. As shown, the SLM 502 has a substrate 503, first bond wires 510A to 501N, second bond wires 511A to 511M, and a die 511. In some examples, the substrate 503 includes or is part of a lead frame, and the die 511 is on the substrate 503. The substrate 503 includes first terminals 504A to 504N, second terminals 505A to 505N, first traces 506A to 506N, second traces 507A to 507M, first bond fingers 508A to 508N, and second bond fingers 509A to 509. The first terminals 504A to 504N are examples of the first terminals 150 of the second IC package 142 in FIG. 1. The second terminals 505A to 505M are examples of the second terminals 152 of the second IC package 142 in FIG. 1. The first bond wires 510A to 510N are examples of the first bond wires 153A of the second IC package 142 in FIG. 1. The second bond wires 511A to 511M are examples of the second bond wires 153B of the second IC package 142 in FIG. 1.

The die 511 is an example of the second die 154 in FIG. 1. In the example of FIG. 5, the die 511 includes first bond pads 512A to 512N, second bond pads 513A to 513B, a programmable connectivity interface 514 (labeled “PCI” in FIG. 5), control circuitry 522, a test interface 526, and a pixel array 530. The first bond pads 512A to 512N are examples of the first bond pads 158 of the second IC package 142 in FIG. 1. The second bond pads 513A to 513M are examples of the second bond pads 160 of the second IC package 142 in FIG. 1. The programmable connectivity interface 514 is an example of the second programmable connectivity interface 162 of the second IC package 142 in FIG. 1. The control circuitry 422 is an example of the second control circuitry 172 of the second IC package 142 in FIG. 1. The test interface 426 is an example of the second test interface 174 of the second IC package 142 in FIG. 1. The pixel array 530 includes an array of memory cells and related microelectromechanical system (MEMS) devices. In some examples, each MEMS device of the pixel array 530 controls and updates the state of a micromirror based on bit plane data and/or configuration data received from an SLM controller.

In the example of FIG. 5, the programmable connectivity interface 514 has first terminals 516A to 516N, second terminals 517A to 517M, third terminals 518, and fourth terminals 520. The first terminals 516A to 516N are examples of the first terminals 164 of the second programmable connectivity interface 162 in FIG. 1. The second terminals 517A to 517M are examples of the second terminals 166 of the second programmable connectivity interface 162 in FIG. 1. The third terminal 518 and the fourth terminal 520 are examples of the third terminals 168 of the second programmable connectivity interface 162 in FIG. 1.

In the example of FIG. 5, the control circuitry 522 has first terminals 524 and second terminals 525. The test interface 526 has terminals 528. The first terminals 524 of the control circuitry 522 are examples of the terminals 173 of the second control circuitry 172 in FIG. 1. The terminals 528 of the test interface 526 are examples of the terminals 175 of the second test interface 174 in FIG. 1. The pixel array 530 has terminal 532.

In the example of FIG. 5, the first terminals 504A to 504N are coupled to respective ones of the first bond fingers 508A to 508N via the first traces 506A to 506N of the substrate 503. The first bond fingers 508A to 508N are coupled to respective ones of the first bond pads 512A to 512N of the die 511 via the first bond wires 510A to 510N. The first bond pads 512A to 512N are coupled to respective ones of the first terminals 516A to 516N of the programmable connectivity interface 514 via traces Data1 to DataN of the die 511. The second terminals 505A to 505M are coupled to respective ones of the second bond fingers 509A to 509M via the second traces 507A to 507M of the substrate 503. The second bond fingers 509A to 509M are coupled to respective ones of the second bond pads 513A to 513M of the die 511 via the second bond wires 511A to 511M. The second bond pads 513A to 513M are coupled to respective ones of the second terminals 517A to 517M of the programmable connectivity interface 514 via traces Backup1 to BackupM of the die 511. The third terminals 518 of the programmable connectivity interface 514 are coupled to the first terminals 524 of the control circuitry 522. The second terminals 525 of the control circuitry 522 are coupled to the terminals 532 of the pixels array 530. The fourth terminals 520 of the programmable connectivity interface 514 are coupled to the terminals 528 of the test interface 526. The connection between the control circuitry 522 and the test interface 526 may be direct (not shown) or may be through the programmable connectivity interface 514.

In some examples, the control circuitry 522 of the SLM 502 operates to: perform connectivity test operations; and perform target SLM operations. Example connectivity test operations include directing the test interface 526 to receive test data from an SLM controller; obtaining connectivity test results responsive to the test data; directing the programmable connectivity interface 514 to update a faulty connection with an available redundant connection; and transmitting the connectivity test results to an SLM controller. An example replacement operation may replace a faulty connection that includes the first terminal 504A, the first trace 506A, the first bond finger 508A, the first bond wire 510A, the first bond pad 512A, and the Data1 trace with a redundant connection that includes the second terminal 505A, the second trace 507A, the second bond finger 509A, the second bond wire 511A, the second bond pad 513A, and the Backup1 trace. In some examples, the SLM 502 supports N data connections and M backup connections, where N is greater than M. Once faulty connections are replaced with redundant connections, the control circuitry 522 is able to perform target SLM operations. Example target SLM operations include: receiving bit plane data and/or configuration data from an SLM controller; and controlling micromirrors of the pixel array 530 responsive to the bit plane data and/or configuration data. In some examples, the operations and circuitry of the control circuitry 522 and the test interface 526 are combined.

In the example of FIG. 5, the first terminals 504A to 504N, the second terminals 505A to 505M, the first bond fingers 508A to 508N, the second bond fingers 509A to 509M, the first bond wires 510A to 510N, the second bond wires 511A to 511M, the first bond pads 512A to 512N, the second bond pads 513A to 513M are represented on the left side of the SLM 502. In other examples, the first terminals 504A to 504N, the second terminals 505A to 505M, the first bond fingers 508A to 508N, the second bond fingers 509A to 509M, the first bond wires 510A to 510N, the second bond wires 511A to 511M, the first bond pads 512A to 512N, the second bond pads 513A to 513M may be: on any one side of the SLM 502; distributed on two sides of the SLM 502; distributed on three sides of the SLM 502; or distributed on four sides of the SLM 502. In different examples, the first terminals 504A to 504N and the second terminals 505A to 505M may be QFN terminals, BGA terminals, DIP terminals, or other external terminal types.

Using redundant terminals (e.g., the second terminals 505A to 505M in FIG. 5, or the second terminals 152 of the second IC package 142 in FIG. 1), redundant bond pads (e.g., the second bond pads 513A to 513M in FIG. 5, or the second bond pads 160 of the second die 154 in FIG. 1), redundant bond wires (e.g., the second bond wires 511A to 511M in FIG. 5, or the second bond wires 153B of the second IC package 142 in FIG. 1), a test interface (e.g., the test interface 526 in FIG. 4, or the second test interface 174 in FIG. 1), and a programmable connectivity interface (e.g., the programmable connectivity interface 514 in FIG. 5, or the second programmable connectivity interface 162 in FIG. 1), the SLM 502 enables on-the-fly in-field repair based on connectivity testing results. Such repairs provide advantages including: automation (without customer intervention); simple to implement; and reduction of field return rate and associated costs. To support such repairs without significant costs, an I/O ring of the SLM 502 has sufficient space for redundant terminals, redundant bond pads, and redundant bond wires. In different examples, the ratio of redundant-to regular connections (e.g., terminals, bond pads, and bond wires) may vary. Also, the placement of redundant connections may vary. In some examples, an SLM or SLM controller has many output-only pins. In some examples, to save cost (of changing to bi-directional connections), an SLM and related SLM controller can rotate driving-detecting roles during the repair process.

In some examples, redundant connections design and programmable connectivity interface design account for time delay and/or time skew tolerances. In some examples, a programmable connectivity interface includes multiplexers, buffers, and storage (see e.g., FIG. 7). By using the same multiplexer type for each connection, the net delay is negligible and the skew impact is small and can be ignored. The buffers for redundant connections account for multiple ending points. In some examples, a distributed buffer structure is used to support a multi-level buffering tree. In some examples, an SLM controller accounts for delay due to buffering by providing signals to redundant connections before providing signals regular connections. In some examples, the delay due to additional trace length (e.g., extra trace from a redundant bond pad to a multiplexer of a replaced bond pad) is relatively small and may vary for each replaced connection. To minimize the skew, the number of redundant connections for each regular connection may be limited to a target ratio (e.g., 1 redundant connection for every 2 to 5 regular connection), where each redundant connection is placed as close as possible to the regular connections that may be replaced.

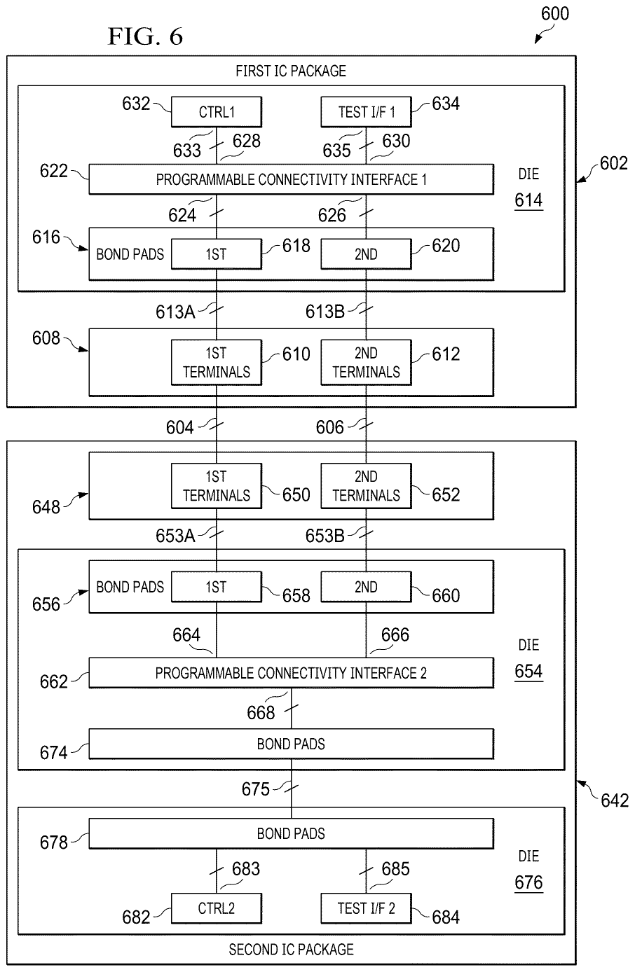

FIG. 6 is a block diagram of circuitry 600 in accordance with various examples. The circuitry 600 of FIG. 6 is similar to the circuitry 100 of FIG. 1, except the second IC package 642 is a multi-die IC package instead of a single-die IC package. In some scenarios, a multi-die IC package, such as the second IC package 642, is preferrable over a single-die IC package to avoid or reduce modification of a particular die (e.g., third die 676 in FIG. 6). In some examples, to avoid modifying the particular die, another die (e.g., the second die 654 in FIG. 6) with a programmable connectivity interface is added between the particular die and external connectors of the multi-die IC module.

In some examples, the circuitry 600 is part of a display, a projector, a vehicle, a manufacturing environment, a battery management system, a feedback loop, or other electronic system with a controller and related controlled circuitry on separate dies. In the example of FIG. 6, circuitry 600 includes a first IC package 602 and a second IC package 642. The first IC package 602 is a single-die IC package having a first die 614 with first control circuitry 632 and a first test interface 634. The second IC package 642 is a multi-die IC package having a second die 654 and a third die 676. The second die 654 includes a second programmable connectivity interface 662. The third die 676 includes second control circuitry 672 and a second test interface 684. In other examples, the second test interface 684 of the second IC package 642 may be included with the second die 654.

As shown, the first IC package 602 includes: a first substrate 608; and the first die 614. In some examples, the first substrate 608 includes or is part of a lead frame that extends underneath the first die 614 and provides a support platform for the first die 614 (see e.g., FIGS. 4 and 5). In FIG. 6, the first substrate 608 includes first terminals 610 and second terminals 612, where the second terminals 612 are redundant terminals relative to the first terminals 610. In some examples, the first terminals 610 and the second terminals 612 are external terminals for the first IC package 602. Example external terminals include, but are not limited to, QFN terminals, BGA terminals, and DIP terminals. In such examples, the first die 614 may be coupled to the external terminals (e.g., the first terminals 610 and the second terminals 612) via die bond pads, substrate bond fingers, bond wires between die bond pads and substrate bond fingers, and substrate traces between substrate bond fingers and the external connectors (see e.g., FIGS. 4 and 5).

In the example of FIG. 6, the first die 614 includes bond pads 616; a first programmable connectivity interface 622; first control circuitry 632; and a first test interface 634. The bond pads 616 includes first bond pads 618 and second bond pads 620, where the second bond pads 620 are redundant bond pads relative to the first bond pads 618. The first programmable connectivity interface 622 has first terminals 624, second terminals 626, third terminals 628, and fourth terminals 630. The first control circuitry 632 has terminals 633. The first test interface 634 has terminals 635.

The first terminals 610 of the first substrate 608 are coupled to the first bond pads 618 of the first die 614 via first bond wires 613A. The second terminals 612 of the first substrate 608 are coupled to the second bond pads 620 of the first die 614 via second bond wires 613B. The first bond pads 618 of the first die 614 are coupled to the first terminals 624 of the first programmable connectivity interface 622. The second bond pads 620 of the first die 614 are coupled to the second terminals 626 of the first programmable connectivity interface 622. The third terminals 628 of the first programmable connectivity interface 622 are coupled to respective ones of the terminals 633 of the first control circuitry 632. The fourth terminals 630 of the first programmable connectivity interface 622 are coupled to respective ones of the terminals 635 of the first test interface 634.

The second IC package 642 includes: a second substrate 648; the second die 654; and the third die 676. In some examples, the second substrate 648 includes or is part of a lead frame that extends underneath the second die 654 and provides a support platform for the second die 654 (see e.g., FIGS. 4 and 5). The second substrate 648 includes first terminals 650 and second terminals 652, where the second terminals 652 are redundant terminals relative to the first terminals 650. In some examples, the first terminals 650 and the second terminals 652 are external terminals for the second IC package 642. Example external terminals include, but are not limited to, QFN terminals, BGA terminals, and DIP terminals. In such examples, the second die 654 may be coupled to the external terminals (e.g., the first terminals 650 and the second terminals 652) via die bond pads, substrate bond fingers, bond wires between die bond pads and substrate bond fingers, and substrate traces between substrate bond fingers and the external connectors (see e.g., FIGS. 4 and 5).

In the example of FIG. 6, the second die 654 includes bond pads 656; a second programmable connectivity interface 662; and bond pads 674. The bond pads 656 includes first bond pads 658 and second bond pads 660, where the second bond pads 660 are redundant bond pads relative to the first bond pads 658. The second programmable connectivity interface 662 has first terminals 664, second terminals 666, third terminals 668. The third die 676 includes bond pads 678, second control circuitry 682, and a second test interface 684. The second control circuitry 682 has terminals 683. The second test interface 684 has terminals 685.

In the example of FIG. 6, each of the first terminals 610 of the first IC package 602 is coupled to a respective terminal of the first terminals 650 of the second IC package 642 via first communication interface lines 604. Each of the second terminals 612 of the first IC package 602 is coupled to a respective terminal of the second terminals 652 of the second IC package 642 via second communication interface lines 606. The first terminals 650 of the second substrate 648 of the second IC package 642 are coupled to the first bond pads 658 of the second die 654 via first bond wires 653A. The second terminals 652 of the second substrate 648 of the second IC package 642 are coupled to the second bond pads 660 of the second die 654 via second bond wires 653B. The first bond pads 658 of the second IC package 642 are coupled to respective terminals of the first terminals 664 of the second programmable connectivity interface 662. The second bond pads 660 of the second IC package 642 are coupled to respective terminals of the second terminals 666 of the second programmable connectivity interface 662. The third terminals 668 of the second programmable connectivity interface 662 are coupled to respective bond pads of the bond pads 674. The bond pads 674 of the second die 654 are coupled to respective bond pads 678 of the third die 676 via bond wires 675. The bond pads 678 are coupled to respective terminals of the terminals 683 of the second control circuitry 682 and respective terminals of the terminals 685 of the second test interface 684.

In some examples, the circuitry 600 performs connectivity test operations. In an example connectivity test, the first test interface 634 provides test data to the second test interface 684 via the first programmable connectivity interface 622, the first bond pads 618 of the first IC package 602, the first bond wires 613A of the first IC package 602, the first terminals 610 of the first IC package 602, the first communication interface lines 604, the first terminals 650 of the second IC package 642, the first bond wires of the second IC package 642, the first bond pads 618 of the second IC package 642, and the first terminals 664 of the second programmable connectivity interface 662. The second test interface 684 analyzes the test data to determine connectivity test results. In some examples, a successful connectivity test indicates the test data from the first test interface 634 is received at the second test interface 684. The test data includes, for example, a single bit value (e.g., a logical “1”) or a multi-bit value (e.g., with at least one logical “1”) for each connection between the first test interface 634 and the second test interface 684.

An example first connection between the first test interface 634 and the second test interface 684 includes: a first of the terminals 635 of the first test interface 634; a first of the fourth terminals 630 of the first programmable connectivity interface 622; a first of the first terminals 624 of the first programmable connectivity interface 622; a first of the first bond pads 618; a first of the first bond wires 613A; a first of the first terminals 610 of the first substrate 608; a first of the first communication interface lines 604; a first of the first terminals 650 of the second substrate 648 of the second IC package 642; a first of the first bond wires 653A of the second die 654; a first of the first bond pads 658; a first of the first terminals 664 of the second programmable connectivity interface 662; a first of the third terminals 668 of the second programmable connectivity interface 662; a first of the bond pads 674; a first of the bond pads 678; and a first of the terminals 685 of the second test interface 684. An example second connection between the first test interface 634 and the second test interface 684 includes: a second of the terminals 635 of the first test interface 634; a second of the fourth terminals 630 of the first programmable connectivity interface 622; a second of the first terminals 624 of the first programmable connectivity interface 622; a second of the first bond pads 618; a second of the first bond wires 613A; a second of the first terminals 610 of the first substrate 608; a second of the first communication interface lines 604; a second of the first terminals 650 of the second substrate 648 of the second IC package 642; a second of the first bond wires 653A of the second die 654; a second of the first bond pads 658; a second of the first terminals 664 of the second programmable connectivity interface 662; a second of the third terminals 668 of the second programmable connectivity interface 662; a second of the bond pads 674; a second of the bond pads 678; and a second of the terminals 685 of the second test interface 684.

If there is a connectivity issue, the second test interface 684 does not receive all test data correctly. In such case, the connectivity test results indicate which connection (or connections) between the first test interface 634 and the second test interface 684 is faulty. To replace a faulty connection with a redundant connection, the programming of first programmable connectivity interface 622 and of the second programmable connectivity interface 662 are updated. If desired, the redundant connection replacing the faulty connection may be tested. After any faulty connections are replaced with redundant connections, the first control circuitry 632 of the first IC package 602 transmits control data to the second control circuitry 682 of the second IC package 642 using the programmed connections. The second control circuitry 682 uses the control data to perform target operations of the second IC package 642.

In one example, the first IC package 602 is an SLM controller, and the second IC package 642 is an SLM. In such examples, the control data transmitted from the first IC package 602 to the second IC package 642 includes bit plane data and configuration data. In response to the bit plane data and the configuration data, the second control circuitry 682 directs the second IC package 642 to control an array of micromirrors responsive to the bit plane data and the configuration data. In some examples, connectivity testing of the second IC package 642 is performed by ATE instead of the first IC package 602.

Using redundant terminals (e.g., the second terminals 612 of the first IC package 602, or the second terminals 652 of the second IC package 642 in FIG. 6), redundant bond pads (e.g., the second bond pads 620 of the first die 614, or the second bond pads 660 of the second die 654 in FIG. 6), redundant bond wires (e.g., the second bond wires 613B of the first IC package 602, or the second bond wires 653B of the second IC package 642 in FIG. 6), test interfaces (e.g., the first test interface 634 of the first IC package 602, or the second test interface 684 of the second IC package 642 in FIG. 6), and programmable connectivity interfaces (e.g., the first programmable connectivity interface 622 of the first IC package 602, or the second programmable connectivity interface 662 of the second IC package 642 in FIG. 6), the first IC package 602 and the second IC package 642 of FIG. 6 enable on-the-fly in-field repair based on connectivity testing results. Such repairs provide advantages including: automation (without customer intervention); simple to implement; and reduction of field return rate and associated costs. To support such repairs without significant costs, an I/O ring of an IC package has sufficient space for redundant terminals, redundant bond pads, and redundant bond wires. In different examples, the ratio of redundant-to regular connections (e.g., terminals, bond pads, and bond wires) may vary. Also, the placement of redundant connections may vary. In some examples, an IC package has many output-only pins. In some examples, to save cost (of changing to bi-directional connections), an IC and related controller can rotate driving-detecting roles during the repair process.

In some examples, redundant connections design and programmable connectivity interface design account for time delay and/or time skew tolerances. In some examples, a programmable connectivity interface includes multiplexers, buffers, and storage (see e.g., FIG. 7). By using the same multiplexer type for each connection, the net delay is negligible and the skew impact is small and can be ignored. The buffers for redundant connections account for multiple ending points. In some examples, a distributed buffer structure is used to support a multi-level buffering tree. In some examples, an IC controller accounts for delay due to buffering by providing signals to redundant connections before providing signals regular connections. In some examples, the delay due to additional trace length (e.g., extra trace from a redundant bond pad to a multiplexer of a replaced bond pad) is relatively small and may vary for each replaced connection. To minimize the skew, the number of redundant connections for each regular connection may be limited to a target ratio (e.g., 1 redundant connection for every 2 to 5 regular connection), where each redundant connection is placed as close as possible to the regular connections that may be replaced.

FIG. 7 is a block diagram showing circuitry 700 of an IC package. Example IC packages that may include the circuitry 700 include the first IC package 102 in FIG. 1, the second IC package 142 in FIG. 1, the first SLM 230 in FIG. 2, the second SLM 242 in FIG. 2, the third SLM 256 in FIG. 2, the fourth SLM 278 in FIG. 2, the fifth SLM 290 in FIG. 2, the first controller 231 in FIG. 2, the second controller 243 in FIG. 2, the third controller 257 in FIG. 2, the fourth controller 279 in FIG. 2, or the fifth controller 291 in FIG. 2, the controller 302 in FIG. 3, the SLM 328 in FIG. 3, the IC package 402 in FIG. 4, the SLM 502 in FIG. 5, the first IC package 602 in FIG. 6, and/or the second IC package 642 in FIG. 6.

As shown, the circuitry 700 includes first bond pads 702A to 702N, second bond pads 704A to 704M, programmable connectivity interface circuitry 706, and test interface circuitry 730. The second bond pads 704A to 704M are redundant bond pads or backup bond pads relative to the first bond pads 702A to 702N. In FIG. 7, the first bond pads 702A to 702N are examples of the first bond pads 118 of the first die 114 in FIG. 1, the first bond pads 158 of the second die 154 in FIG. 1, the first bond pads 412A to 412N of the die 411 in FIG. 4, the first bond pads 512A to 512N of the die 511 in FIG. 5, the first bond pads 618 of the first die 614 in FIG. 6, or the first bond pads of the second die 654 in FIG. 6. The programmable connectivity interface circuitry 706 is example circuitry of the first programmable connectivity interface 622 in FIG. 1, the second programmable connectivity interface 162 in FIG. 1, the programmable connectivity interface 414 in FIG. 4, the programmable connectivity interface 514 in FIG. 5, the first programmable connectivity interface 622 in FIG. 6, or the second programmable connectivity interface 662 in FIG. 6. The test interface circuitry 730 is example circuitry of the first test interface 134 in FIG. 1, the second test interface 174 in FIG. 1, the test interface 426 in FIG. 4, the test interface 526 in FIG. 5, the first test interface 634 in FIG. 6, or the second test interface 684 in FIG. 6.

In the example of FIG. 7, the programmable connectivity interface circuitry 706 includes first buffers 708A to 708N, second buffers 714A to 714M, and multiplexers 720A to 720N. The test interface circuitry 730 includes latches 732A to 732N. The first buffers 708A to 708N have respective first terminals 710A to 710N and respective second terminals 712A to 712N. The second buffers 714A to 714M have respective first terminals 716A to 716M and respective second terminals 718A to 718M. The multiplexers 720A to 720N have respective first terminals 722A to 722N, respective second terminals 724A to 724N, respective third terminal 726A to 726N, and respective fourth terminals 728A to 728N. The latches 732A to 732N have respective first terminals 734A to 734N and respective second terminals 736A to 736N.

In the example of FIG. 7, the first bond pads 702A to 702N are coupled to respective terminals of the first terminals 710A to 710N of the first buffers 708A to 708N. The second terminals 712A to 712N of the first buffers 708A to 708N are coupled to respective terminals of the first terminals 722A to 722N of the multiplexers 720A to 720N. The second bond pads 704A to 704M are coupled to respective terminals of the first terminals 716A to 716M of the second buffers 714A to 714M. The second terminals 718A to 718M of the second buffers 714A to 714M are coupled to respective terminals of the second terminals 724A to 724N of the multiplexers 720A to 720N. The third terminals 726A to 726N of the multiplexers 720A to 720N are coupled to respective terminals of the second terminals 736A to 736N of the latches 732A to 732N. The fourth terminals 728A to 728N of the multiplexers 720A to 720N are coupled to respective terminals of the first terminals 734A to 734N of the latches 732A to 732N.

In the example of FIG. 7, test data received at the first bond pads 702A to 702N is conveyed to the latches 732A to 732N via the first buffers 708A to 708N and the multiplexers 720A to 720N. The latches 732A to 732N store the test data as connectivity test results. In some examples, the test data includes a logical “1” for each of the latches 732A to 732N. If one of the latches 732A to 732N does not store a logical “1” responsive to a connectivity test, a related faulty connection is identified and a respective backup bond pad of the second bond pads 704A to 704M is selected to replace the fault connection. To replace the faulty connection, a respective multiplexer of the multiplexers 720A to 720N receives a control signal at its third terminal (e.g., the third terminals 726A to 726N) to forward data from its second terminal (e.g., the second terminals 724A to 724N) to its fourth terminal (e.g., the fourth terminals 728A to 728N) instead of data from its first terminal (e.g., the first terminals 722A to 722N).

In the example of FIG. 7, there is a second bond pad (e.g., the second bond pads 704A to 704M) for every three first bond pads (e.g., the first bond pads 702A to 702N), where the second bond pads are redundant bond pads or backup bond pads relative to the first bond pads. In other examples, the number of second bond pads relative to the number of first bond pads may vary.

After connectivity testing and updates are performed, target operations of an IC package may be performed using the circuitry 700. In some examples, during such target operations, control data and/or configuration data are transferred from a first IC package (e.g., a controller) to a second IC package (e.g., a controlled IC). The control data and/or the configuration data may be stored in the latches 732A to 732N for later use. In an SLM example, the latches 732A to 732N may store bit plane data and/or configuration data for use in controlling an array of micromirrors.

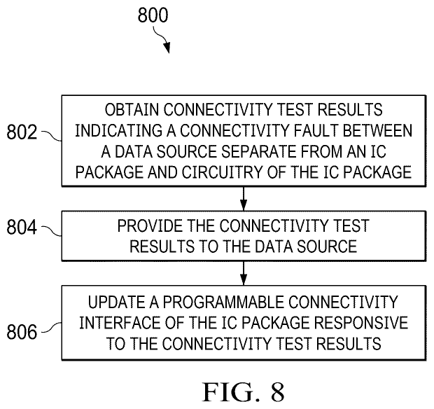

FIG. 8 is a flowchart showing a connectivity update method 800 in accordance with various examples. The connectivity update method 800 may be performed by an IC package (e.g., the second IC package 142 in FIG. 1, each SLM in FIG. 2, the SLM 328 in FIG. 3, the IC package 402 in FIG. 4, the SLM 502 in FIG. 5, the second IC package 642 in FIG. 6, or the circuitry 700 in FIG. 7). In some examples, the connectivity update method 800 includes obtaining connectivity test results indicating a connectivity fault between a data source (e.g., another IC package or an ATE) separate from an IC package and circuitry of the IC package at block 802. In some examples, the connectivity test results are provided to the data source at block 804. In other examples, connectivity test results are not provided to the data source (e.g., an IC package may use the connectivity test results for internal connectivity updates without sharing the connectivity test results). At block 806, a programmable connectivity interface of the IC package is updated responsive to the connectivity test results. Updating the programmable connectivity interface replaces a faulty connection with a redundant connection so that communications can be received by circuitry (e.g., control circuitry and/or a test interface) of an IC package even if there are some faulty connections.

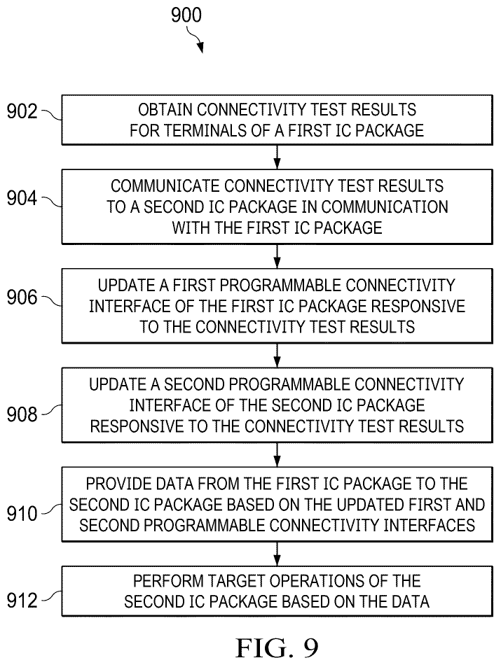

FIG. 9 is a flowchart showing a connectivity update method 900 in accordance with various examples. The connectivity update method 900 may be performed by circuitry (e.g., the circuitry 100 in FIG. 1, each controller and SLM pair in FIG. 2, the controller 302 and the SLM 328 in FIG. 3, circuitry of the die 411 in FIG. 4, circuitry of the die 511 in FIG. 5, the circuitry 600 in FIG. 6, or the circuitry 700 in FIG. 7.

In some examples, the method 900 includes obtaining connectivity test results for terminals of a first IC package (e.g., the second IC package 142 in FIG. 1, the first SLM 230 in FIG. 2, the second SLM 242 in FIG. 2, the third SLM 256 in FIG. 2, the fourth SLM 278 in FIG. 2, the fifth SLM 290 in FIG. 2, the SLM 328 in FIG. 3, the IC package 402 in FIG. 4, the SLM 502 in FIG. 5, the second IC package 642 in FIG. 6) at block 902. At block 904, connectivity test results are communicated to a second IC package (e.g., the first IC package 102 in FIG. 1, the first controller 231 in FIG. 2, the second controller 243 in FIG. 2, the third controller 257 in FIG. 2, the fourth controller 279 in FIG. 2, the fifth controller 291 in FIG. 2, the controller 302 in FIG. 3, or the first IC package 602 in FIG. 6) in communication with the first IC package. At block 906, a first programmable connectivity interface (e.g., the second programmable connectivity interface 162 in FIG. 1, the programmable connectivity interface 414 in FIG. 4, the programmable connectivity interface 514 in FIG. 5, the second programmable connectivity interface 662 in FIG. 6) of the first IC package is updated responsive to the connectivity test results. At block 908, a second programmable connectivity interface (e.g., the first programmable connectivity interface 122 in FIG. 1, or the first programmable connectivity interface 622 in FIG. 6) of the second IC package is updated responsive to the connectivity test results. At block 910, data is provided from the first IC package to the second IC package based on the updated first and second programmable connectivity interfaces. At block 912, target operations of the second IC package are performed based on the data.

In some examples, the method 800 is performed by an SLM controller and an SLM. Once connectivity is tested and updated as needed, the SLM controller transmits bit plane data and/or configuration data to the SLM. In response to the bit plane data and/or configuration data, the SLM controls an array of micro mirrors.

In some examples, an IC package (e.g., the second IC package 142 in FIG. 1, the IC package 402 in FIG. 4, any of the SLMs in FIG. 2, the SLM 328 in FIG. 3, the IC package 402 in FIG. 4, the SLM 502 in FIG. 5, or the second IC package 642 in FIG. 6) includes: a substrate; a die; first bond wires; and second bond wires. In such examples, the substrate (e.g., the second substrate 148 in FIG. 1, the substrate 403 in FIG. 4, the substrate 503 in FIG. 5, or the second substrate 648 in FIG. 6) has terminals including first terminals (e.g., the first terminals 150 in FIG. 1, the first terminals 404A to 404N in FIG. 4, the first terminals 504A to 504N in FIG. 5, the first terminals 650 in FIG. 6) and second terminals (e.g., the second terminals 152 in FIG. 1, the second terminals 405A to 405M in FIG. 4, the second terminals 505A to 505M in FIG. 5, the second terminals 652 in FIG. 6). The second terminals are redundant terminals relative to the first terminals.

In such examples, the die (e.g., the second die 154 in FIG. 1, the die 411 in FIG. 4, the die 511 in FIG. 5, or the second die 654 and third die 676 in FIG. 6) has bond pads including first bond pads (e.g., the first bond pads 158 in FIG. 1, the first bond pads 412A to 412N in FIG. 4, the first bond pads 512A to 512N in FIG. 5, the first bond pads 658 in FIG. 6) and second bond pads (e.g., the second bond pads 160 in FIG. 1, the second bond pads 413A to 413M in FIG. 4, the second bond pads 513A to 513M in FIG. 5, the second bond pads 660 in FIG. 6). The second bond pads are redundant bond pads relative to the first bond pads.

In such examples, the die includes control circuitry (e.g., the second control circuitry 172 in FIG. 1, control circuitry of the first SLM 230 in FIG. 2, control circuitry of the second SLM 242 in FIG. 2, control circuitry of the third SLM 256 in FIG. 2, control circuitry of the fourth SLM 278 in FIG. 2, control circuitry of the fifth SLM 290 in FIG. 2, control circuitry of the SLM 328 in FIG. 3, the control circuitry 422 in FIG. 4, the control circuitry 522 in FIG. 5, the first control circuitry 632 in FIG. 6, or the second control circuitry 682 in FIG. 6) and a programmable connectivity interface (e.g., the second programmable connectivity interface 162 in FIG. 1, a programmable connectivity interface of the first SLM 230 in FIG. 2, a programmable connectivity interface of the second SLM 242 in FIG. 2, a programmable connectivity interface of the third SLM 256 in FIG. 2, a programmable connectivity interface of the fourth SLM 278 in FIG. 2, a programmable connectivity interface of the fifth SLM 290 in FIG. 2, a programmable connectivity interface of the SLM 328 in FIG. 3, the programmable connectivity interface 414 in FIG. 4, the programmable connectivity interface 514 in FIG. 5, the second programmable connectivity interface 662 in FIG. 6, or the programmable connectivity interface circuitry 706 in FIG. 7). The programmable connectivity interface is coupled between the first bond pads and the circuitry. The programmable connectivity interface is also coupled between the second bond pads and the circuitry. The first bond wires are coupled between the first terminals and respective bond pads of the first bond pads. The second bond wires are coupled between the second terminals and respective bond pads of the second bond pads.

In some examples, the circuitry includes test interface circuitry (e.g., the second test interface 174 in FIG. 1, the test interface 426 in FIG. 4, the test interface 526 in FIG. 5, the second test interface 684 in FIG. 6, the test interface circuitry 730 in FIG. 7). The test interface circuitry includes storage elements (e.g., the latches 732A to 732N) including a respective storage element for each of the first bond pads and second bond pads. In some examples, the programmable connectivity interface includes a multiplexer (e.g., the multiplexers 720A to 720N in FIG. 7) having a first terminal (e.g., the first terminals 722A to 722N in FIG. 7), a second terminal (e.g., the second terminals 724A to 724N in FIG. 7), a third terminal (e.g., the third terminals 726A to 726N in FIG. 7), and a fourth terminal (e.g., the fourth terminals 728A to 728N in FIG. 7). The first terminal of the multiplexer coupled to a respective bond pad of the first bond pads. The second terminal of the multiplexer coupled to a respective bond pad of the second bond pads. The third terminal of the multiplexer is coupled to an output terminal (e.g., a respective terminal of the second terminals 736A to 736N in FIG. 7) of a respective storage element of the storage elements. The fourth terminal of the multiplexer is coupled to an input terminal (e.g., a respective terminal of the first terminals 734A to 734N in FIG. 7) of the respective storage element.

In some examples, the programmable connectivity interface includes a first multiplexer (e.g., the multiplexer 720A) and a second multiplexer (e.g., the multiplexer 720B). The first multiplexer has a first terminal (e.g., the first terminal 722A in FIG. 7), a second terminal (e.g., the second terminal 724A in FIG. 7), a third terminal (e.g., the third terminal 726A in FIG. 7), and a fourth terminal (e.g., the fourth terminal 728A in FIG. 7). The second multiplexer has a first terminal (e.g., the first terminal 722B in FIG. 7), a second terminal (e.g., the second terminal 724B in FIG. 7), a third terminal (e.g., the third terminal 726B in FIG. 7), and a fourth terminal (e.g., the fourth terminal 728B in FIG. 7). The first terminal of the first multiplexer is coupled to a first respective bond pad (e.g., the first bond pad 702A in FIG. 7) of the first bond pads (e.g., the first bond pads 702A to 702N in FIG. 7). The second terminal of the first multiplexer coupled to a first respective bond pad (e.g., the second bond pad 704A) of the second bond pads (e.g., the second bond pads 704A to 704M). The third terminal of the first multiplexer is coupled to an output terminal (e.g., the second terminal 736A in FIG. 7) of a first respective storage element (e.g., the latch 732A in FIG. 7) of the storage elements (e.g., the latches 732A to 732N in FIG. 7). The fourth terminal of the first multiplexer is coupled to an input terminal (e.g., the first terminal 734A in FIG. 7) of the first respective storage element (e.g., the latch 732A). The first terminal of the second multiplexer is coupled to a second respective bond pad (e.g., the first bond pads 702B in FIG. 7) of the first bond pads (e.g., the first bond pads 702A to 702N in FIG. 7). The second terminal of the second multiplexer is coupled to the first respective bond pad (e.g., a second bond pad 704B - not specifically shown) of the second bond pads (e.g., the second bond pads 704A to 704M in FIG. 7). The third terminal of the second multiplexer is coupled to an output terminal (e.g., the second terminal 736B in FIG. 7) of a second respective storage element (e.g., the latch 732B in FIG. 7) of the storage elements (e.g., the latches 732A to 732N in FIG. 7). The fourth terminal of the second multiplexer is coupled to an input terminal (e.g., the first terminal 734B in FIG. 7) of the second respective storage element (e.g., the latch 732B in FIG. 7). In some examples, there are more first bond pads (e.g., the first bond pads 702A to 702N in FIG. 7) than second bond pads (e.g., the second bond pads 704A to 704M in FIG. 7).

In some examples, the IC package is a first IC package (e.g., the second IC package 142 in FIG. 1, one of the SLMs in FIG. 2, the SLM 328 in FIG. 3, the IC package 402 in FIG. 4, the SLM 502 in FIG. 5, or the second IC package 642 in FIG. 6), and the circuitry is configured to detect a connectivity fault preventing communications from a data source (e.g., the first IC package 102 in FIG. 1, the first controller 231 in FIG. 2, the second controller 243 in FIG. 2, the third controller 257 in FIG. 2, the fourth controller 279 in FIG. 2, the fifth controller 291 in FIG. 2, the controller 302 in FIG. 3, the first IC package 602 in FIG. 6, or an ATE) via a terminal of the first terminals (e.g., the first terminals 150 of the second IC package 142 in FIG. 1, the first terminals 404A to 404N in FIG. 4, the first terminals 504A to 504N in FIG. 5, the first terminals 650 of the second IC package 642 in FIG. 6), a respective bond wire (e.g., a respective bond wire of the first bond wires 153A in FIG. 1, a respective bond wire of the first bond wires 410A to 410N in FIG. 4, a respective bond wire of the first bond wires 510A to 510N in FIG. 5, a respective bond wire of the first bond wires 653A in FIG. 6), and a respective bond pad of the first bond pads (e.g., the first bond pads 158 in FIG. 1, the first bond pads 412A to 412N in FIG. 4, the first bond pads 512A to 512N in FIG. 5, or the first bond pads 658 in FIG. 6). In such examples, the circuitry is configured to update the programmable connectivity interface responsive to the detected connectivity fault.

In some examples, the IC package is a first IC package (e.g., the second IC package 142 in FIG. 1, the IC package 402 in FIG. 4, the SLM 502 in FIG. 5, or the second IC package 642 in FIG. 6), the data source is a second IC package (e.g., the first IC package 102 in FIG. 1, the first controller 231 in FIG. 2, the second controller 243 in FIG. 2, the third controller 257 in FIG. 2, the fourth controller 279 in FIG. 2, the fifth controller 291 in FIG. 2, the controller 302 in FIG. 3, the first IC package 602 in FIG. 6), and the circuitry is configured to obtain connectivity test results indicating a connectivity fault preventing communications from the second IC package via a terminal of the first terminals (e.g., the first terminals 150 of the second IC package 142 in FIG. 1, the first terminals 404A to 404N in FIG. 4, the first terminals 504A to 504N in FIG. 5, the first terminals 650 of the second IC package 642 in FIG. 6), a respective bond wire (e.g., a respective bond wire of the first bond wires 153A in FIG. 1, a respective bond wire of the first bond wires 410A to 410N in FIG. 4, a respective bond wire of the first bond wires 510A to 510N in FIG. 5, a respective bond wire of the first bond wires 653A in FIG. 6), and a respective bond pad of the first bond pads (e.g., the first bond pads 158 in FIG. 1, the first bond pads 412A to 412N in FIG. 4, the first bond pads 512A to 512N in FIG. 5, or the first bond pads 658 in FIG. 6). In such examples, the circuitry is configured to: provide the connectivity test results to the second IC package; and update the programmable connectivity interface responsive to the programmable connectivity interface updates.

In some examples, the data source is ATE, and the circuitry is configured to: obtain connectivity test results indicating a connectivity fault preventing communications from the ATE via a terminal of the first terminals, a respective bond wire, and a respective bond pad of the first bond pads; and update the programmable connectivity interface responsive to the connectivity test results.

In some examples, the first terminals (e.g., the first terminals 150 in FIG. 1, the first terminals 404A to 404N in FIG. 4, the first terminals 504A to 504N in FIG. 5, the first terminals 650 in FIG. 6) include higher speed communication interface terminals and lower speed communication interface terminals. In such examples, the first bond pads (e.g., the first bond pads 158 in FIG. 1, the first bond pads 412A to 412N in FIG. 4, the first bond pads 512A to 512N in FIG. 5, or the first bond pads 658 in FIG. 6) include higher speed communication interface bond pads and lower speed interface bond pads.

In such examples, the circuitry (e.g., the circuitry 100 in FIG. 1, the first SLM 230 and the first controller 231 in FIG. 2, the first SLM 230 and the first controller 231 in FIG. 2, the second SLM 242 and the second controller 243 in FIG. 2, the third SLM 256 and the third controller 257 in FIG. 2, the fourth SLM 278 and the fourth controller 279 in FIG. 2, the fifth SLM 290 and the fifth controller 291 in FIG. 2, the controller 302 and the SLM 328 in FIG. 3, or the circuitry 600 in FIG. 6) includes: controller (e.g., the control circuitry 522 in FIG. 5) coupled to the first set of the terminals and the second set of the terminals (e.g., via the programmable connectivity interface 514 in FIG. 5); and a DMD coupled to the controller, wherein the second terminals provide redundancy for the higher speed communication interface terminals and the second bond pads provide redundancy for the higher speed communication interface bond pads. The amount of redundancy for a particular IC package or higher speed communication interface may be based on available I/O ring space of an IC package, previous testing of an IC package or higher speed communication interface, and end-use environment (e.g., ambient temperature, temperature range, vibration, or other stress-related parameters that may introduce connectivity faults).

In some examples, an IC (e.g., the second IC package 142 in FIG. 1, the IC package 402 in FIG. 4, the SLM 502 in FIG. 5, or the second IC package 642 in FIG. 6) includes: bond pads including first bond pads (e.g., the first bond pads 158 in FIG. 1, the first bond pads 412A to 412N in FIG. 4, the first bond pads 512A to 512N in FIG. 5, or the first bond pads 658 in FIG. 6) and second bond pads (e.g., the second bond pads 160 in FIG. 1, the second bond pads 413A to 413N in FIG. 4, the second bond pads 513A to 513N in FIG. 5, or the second bond pads 660 in FIG. 6), the second bond pads redundant relative to the first bond pads; circuitry (e.g., the second control circuitry 172 and/or the second test interface 174 in FIG. 1, the control circuitry 422 and/or the test interface 426 in FIG. 4, the control circuitry 522 and/or the test interface 526 in FIG. 5, the second control circuitry 682 and/or the second test interface 684 in FIG. 6); and a programmable connectivity interface (e.g., the second programmable connectivity interface 162 in FIG. 1, the programmable connectivity interface 414 in FIG. 4, the programmable connectivity interface 514 in FIG. 5, or the second programmable connectivity interface 662 in FIG. 6) coupled between the bond pads and the circuitry. In such examples, the circuitry (e.g., the second control circuitry 172 and/or the second test interface 174 in FIG. 1, the control circuitry 422 and/or the test interface 426 in FIG. 4, the control circuitry 522 and/or the test interface 526 in FIG. 5, or the second control circuitry 682 and/or the second test interface 684 in FIG. 6) is configured to: obtain connectivity test results indicating a connectivity fault preventing communications from a data source separate from the IC via a bond pad of the first bond pads; and update the programmable connectivity interface responsive to the connectivity test results.

In such examples, the IC is a first IC, the data source is a second IC (e.g., the first IC package 102 in FIG. 1, the first controller 231 in FIG. 2, the second controller 243 in FIG. 2, the third controller 257 in FIG. 2, the fourth controller 279 in FIG. 2, the fifth controller 291 in FIG. 2, the controller 302 in FIG. 3, the first IC package 602 in FIG. 6), and the circuitry is configured to provide the connectivity test results to the second IC.

In some examples, the data source is ATE and the circuitry is configured to:
obtain test data from the ATE; and determine the connectivity test results responsive to the test data.

In some examples, a first set of the bond pads (e.g., a first set of the first bond pads 158 in FIG. 1, a first set of the first bond pads 412A to 412N in FIG. 4, a first set of the first bond pads 512A to 512N in FIG. 5, or a first set of the first bond pads 658 in FIG. 6) are communication interface bond pads, the circuitry (e.g., the second control circuitry 172 and/or the second test interface 174 in FIG. 1, the control circuitry 422 and/or the test interface 426 in FIG. 4, the control circuitry 522 and/or the test interface 526 in FIG. 5, or the second control circuitry 682 and/or the second test interface 684 in FIG. 6) includes control circuitry (e.g., the second control circuitry 172 in FIG. 1, the control circuitry 422 in FIG. 4, the control circuitry 522 in FIG. 5, or the second control circuitry 682 in FIG. 6) coupled to the first set of the bond pads, and the programmable connectivity interface is configured to selectively replace connection of a bond pad of the first set of the bond pads to the control circuitry with connection of a bond pad of the second bond pads to the control circuitry.

In some examples, the circuitry (e.g., the second control circuitry 172 and/or the second test interface 174 in FIG. 1, the control circuitry 422 and/or the test interface 426 in FIG. 4, the control circuitry 522 and/or the test interface 526 in FIG. 5, or the second control circuitry 682 and/or the second test interface 684 in FIG. 6) includes a DMD pixel array (e.g., the pixel array 530 in FIG. 5) coupled to the control circuitry, wherein the second bond pads provide a redundancy between 10% and 40% for the first set of the bond pads.

In some examples, an apparatus (e.g., a projector, a display, or other apparatus) includes: a controller (e.g., the first IC package 102 in FIG. 1, the first controller 231 in FIG. 2, the second controller 243 in FIG. 2, the third controller 257 in FIG. 2, the fourth controller 279 in FIG. 2, the fifth controller 291 in FIG. 2, the controller 302 in FIG. 3, or the first IC package 602 in FIG. 2; an IC package (e.g., the second IC package 142 in FIG. 1, the first SLM 230 in FIG. 2, the second SLM 242 in FIG. 2, the third SLM 256 in FIG. 2, the fourth SLM 278 in FIG. 2, the fifth SLM 290 in FIG. 2, the SLM 328 in FIG. 3, the IC package 402 in FIG. 4, the SLM 502 in FIG. 5, or the second IC package 642 in FIG. 6) coupled to the controller; and a communication interface (e.g., the first communication interface lines 104 and the second communication interface lines 106 in FIG. 1, or the first communication interface lines 604 and the second communication interface lines 606 in FIG. 6) coupled between the controller and the IC package.

In such examples, the IC package includes: a substrate (e.g., the second substrate 148 in FIG. 1, the substrate 403 in FIG. 4, the substrate 503 in FIG. 5, or the second substrate 648 in FIG. 6) having terminals including first terminals (e.g., the first terminals 150 in FIG. 1, the first terminals 404A to 404N in FIG. 4, the first terminal 504A to 504N in FIG. 5, or the first terminals 650 in FIG. 6) and second terminals (e.g., the second terminals 152 in FIG. 1, the second terminals 405A to 405M in FIG. 4, the second terminal 505A to 505M in FIG. 5, or the second terminals 652 in FIG. 6) related to the communication interface, the second terminals being redundant terminals relative to the first terminals; a die (e.g., the second die 154 in FIG. 1, the die 411 in FIG. 4, the die 511 in FIG. 5, or the second die 654 and/or the third die 676 in FIG. 6) including bond pads, circuitry (e.g., the second control circuitry 172 and/or the second test interface 174 in FIG. 1, the control circuitry 422 and/or the test interface 426 in FIG. 4, the control circuitry 522 and/or the test interface 526 in FIG. 5, or the second control circuitry 682 and/or the second test interface 684 in FIG. 6), and a programmable connectivity interface (e.g., the second programmable connectivity interface 162, the programmable connectivity interface 414 in FIG. 4, the programmable connectivity interface 514 in FIG. 5, or the second programmable connectivity interface 662 in FIG. 6). The bond pads includes first bond pads (e.g., the first bond pads 158 in FIG. 1, the first bond pads 412A to 412N in FIG. 4, the first bond pads 512A to 512N in FIG. 5, or the first bond pads 658 in FIG. 6) and second bond pads (e.g., the second bond pads 160 in FIG. 1, the second bond pads 413A to 413M in FIG. 4, the second bond pads 513A to 513M in FIG. 5, or the second bond pads 660 in FIG. 6) related to the communication interface, the second bond pads being redundant bond pads relative to the first bond pads. In such examples, the programmable connectivity interface is coupled between the bond pads and the circuitry. In such examples, the IC package also includes first bond wires (e.g., the first bond wires 153A in FIG. 1, the first bond wires 410A to 410N in FIG. 4, the first bond wires 510A to 510N in FIG. 5, or the first bond wires 653A in FIG. 6) coupled between the first terminals and respective bond pads of the first bond pads; and second bond wires (e.g., the second bond wires 153B in FIG. 1, the second bond wires 411A to 411M in FIG. 4, the second bond wires 511A to 511M in FIG. 5, or the second bond wires 653B in FIG. 6) coupled between the second terminals and respective bond pads of the second bond pads. In some examples, the controller is a DMD controller, and the circuitry includes a DMD.

In some examples, the communication interface is a higher speed communication interface, and the apparatus comprises a lower speed communication interface coupled between the controller and the IC package. In some examples, the second terminals provide a redundancy between 10% and 40% for the first terminals, and the second bond pads provide a redundancy between 10% and 40% for the first bond pads.

In some examples, the substrate is a first substrate, the die is a first die, the programmable connectivity interface is a first programmable connectivity interface, and the controller includes: a second substrate (e.g., the first substrate 108 in FIG. 1, or the first substrate 608 in FIG. 6) having terminals including first terminals (e.g., the first terminal 110 in FIG. 1, or the first terminal 610 in FIG. 6) and second terminals (e.g., the second terminal 112 in FIG. 1, or the second terminal 612 in FIG. 1) related to the communication interface, the second terminals of the second substrate being redundant terminals relative to the first terminals of the second substrate. In such examples, the controller includes a second die (e.g., the first die 114 in FIG. 1, or the first die 614 in FIG. 6) including bond pads, first control circuitry (e.g., the first control circuitry 132 in FIG. 1, or the first control circuitry 632 in FIG. 6), a first test interface (e.g., the first test interface 134 in FIG. 1, or the first test interface 634 in FIG. 6), and a second programmable connectivity interface (e.g., the first programmable connectivity interface 122 in FIG. 1, or the first programmable connectivity interface 622 in FIG. 6). In such examples, the bond pads including first bond pads (e.g., the first bond pads 118 in FIG. 1, or the first bond pads 618 in FIG. 6) and second bond pads (e.g., the second bond pads 120 in FIG. 1, or the second bond pads 620 in FIG. 6) related to the communication interface, the second bond pads of the second die being redundant bond pads relative to the first bond pads of the second die. In such examples, the programmable connectivity interface is coupled between the bond pads of the second die and the circuitry of the second die.

In such examples, the controller includes third bond wires (e.g., the first bond wires 113A in FIG. 1, or the first bond wires 613A in FIG. 6) coupled between the first terminals of the second substrate and respective bond pads of the first bond pads of the second die; and fourth bond wires (e.g., the second bond wires 113B in FIG. 1, or the second bond wires 613B in FIG. 6) coupled between the second terminals of the second substrate and respective bond pads of the second bond pads of the second die.

In such examples, the controller is configured to: send test data to the IC package; receive connectivity test results from the IC package responsive to the test data; update the programmable connectivity interface of the controller responsive to the connectivity test results; and send instructions to the IC package to update the programmable connectivity interface of the IC package responsive to the connectivity test results.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated circuit. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

In this description, unless otherwise stated, “about,” “approximately” or “substantially” preceding a parameter means being within +/−10 percent of that parameter or, if the parameter is zero, a reasonable range of values around zero.

Modifications are possible in the described examples, and other examples are possible, within the scope of the claims.

1. An integrated circuit (IC) package comprising:
a substrate having terminals including first terminals and second terminals, the second terminals being redundant terminals relative to the first terminals;
a die having bond pads including first bond pads and second bond pads, the second bond pads being redundant bond pads relative to the first bond pads, the die including circuitry and a programmable connectivity interface, the programmable connectivity interface coupled between the first bond pads and the circuitry, and the programmable connectivity interface coupled between the second bond pads and the circuitry;
first bond wires coupled between the first terminals and respective bond pads of the first bond pads; and
second bond wires coupled between the second terminals and respective bond pads of the second bond pads.

2. The IC package of claim 1, wherein the circuitry includes test interface circuitry, and the test interface circuitry includes storage elements including a respective storage element for each of the first bond pads and second bond pads.

3. The IC package of claim 2, wherein the programmable connectivity interface includes a multiplexer having a first terminal, a second terminal, a third terminal, and a fourth terminal, the first terminal of the multiplexer coupled to a respective bond pad of the first bond pads, the second terminal of the multiplexer coupled to a respective bond pad of the second bond pads, the third terminal of the multiplexer coupled to an output terminal of a respective storage element of the storage elements, and the fourth terminal of the multiplexer coupled to an input terminal of the respective storage element.

4. The IC package of claim 2, wherein the programmable connectivity interface includes a first multiplexer and a second multiplexer, the first multiplexer having a first terminal, a second terminal, a third terminal, and a fourth terminal, the second multiplexer having a first terminal, a second terminal, a third terminal, and a fourth terminal, the first terminal of the first multiplexer coupled to a first respective bond pad of the first bond pads, the second terminal of the first multiplexer coupled to a first respective bond pad of the second bond pads, the third terminal of the first multiplexer coupled to an output terminal of a first respective storage element of the storage elements, and the fourth terminal of the first multiplexer coupled to an input terminal of the first respective storage element, the first terminal of the second multiplexer coupled to a second respective bond pad of the first bond pads, the second terminal of the second multiplexer coupled to the first respective bond pad of the second bond pads, the third terminal of the second multiplexer coupled to an output terminal of a second respective storage element of the storage elements, and the fourth terminal of the second multiplexer coupled to an input terminal of the second respective storage element.

5. The IC package of claim 1, wherein there are more first bond pads than second bond pads.

6. The IC package of claim 1, wherein the IC package is a first IC package, and the circuitry is configured to:
obtain connectivity test results indicating a connectivity fault between the circuitry and a data source separate from the first IC package; and
update the programmable connectivity interface responsive to the connectivity test results.

7. The IC package of claim 6, wherein the circuitry is configured to provide the connectivity test results to the data source.

8. The IC package of claim 6, wherein the data source is automated test equipment (ATE).

9. The IC package of claim 1, wherein the first terminals include higher speed communication interface terminals and lower speed communication interface terminals, the first bond pads include higher speed communication interface bond pads and lower speed communication interface bond pads, and the circuitry includes:
a controller coupled to the higher speed communication interface terminals and the lower speed communication interface terminals; and
a digital micromirror device (DMD) coupled to the controller, wherein the second terminals provide redundancy for the higher speed communication interface terminals and the second bond pads provide redundancy for the higher speed communication interface bond pads.

10. An integrated circuit (IC) comprising:
bond pads including first bond pads and second bond pads, the second bond pads redundant relative to the first bond pads;
circuitry; and
a programmable connectivity interface coupled between the bond pads and the circuitry, wherein the circuitry is configured to:
obtain connectivity test results indicating a connectivity fault between the circuitry and a data source separate from the IC; and
update the programmable connectivity interface responsive to the connectivity test results.

11. The IC of claim 10, wherein the IC is a first IC, the data source is a second IC, and the circuitry is configured to provide the connectivity test results to the second IC.

12. The IC of claim 10, wherein the data source is automated test equipment (ATE) and the circuitry is configured to:
obtain test data from the ATE; and
determine the connectivity test results responsive to the test data.

13. The IC of claim 10, wherein a first set of the bond pads are communication interface bond pads, the circuitry includes control circuitry coupled to the first set of the bond pads, and the programmable connectivity interface is configured to selectively replace connection of a bond pad of the first set of the bond pads to the control circuitry with connection of a bond pad of the second bond pads to the control circuitry.

14. The IC of claim 13, wherein the circuitry includes a DMD coupled to the control circuitry, wherein the second bond pads provide a redundancy between 10% and 40% for the first set of the bond pads.

15. An apparatus comprising:
a controller;
an integrated circuit (IC) package coupled to the controller; and
a communication interface coupled between the controller and the IC package, the IC package including:
a substrate having terminals including first terminals and second terminals related to the communication interface, the second terminals being redundant terminals relative to the first terminals;
a die including bond pads, circuitry, and a programmable connectivity interface, the bond pads including first bond pads and second bond pads related to the communication interface, the second bond pads being redundant bond pads relative to the first bond pads, the programmable connectivity interface coupled between the bond pads and the circuitry;
first bond wires coupled between the first terminals and respective bond pads of the first bond pads; and
second bond wires coupled between the second terminals and respective bond pads of the second bond pads.

16. The apparatus of claim 15, wherein the IC package includes a DMD.

17. The apparatus of claim 15, wherein the communication interface is a higher speed communication interface, and the apparatus comprises a lower speed communication interface coupled between the controller and the IC package.

18. The apparatus of claim 15, wherein the second terminals provide a redundancy between 10% and 40% for the first terminals, the second bond pads provide a redundancy between 10% and 40% for the first bond pads, and the second bond wires provide a redundancy between 10% and 40% for the first bond wires.

19. The apparatus of claim 15, wherein the substrate is a first substrate, the die is a first die, the programmable connectivity interface is a first programmable connectivity interface, and the controller includes:
a second substrate having terminals including first terminals and second terminals related to the communication interface, the second terminals of the second substrate being redundant terminals relative to the first terminals of the second substrate;
a second die including bond pads, circuitry, and a second programmable connectivity interface, the bond pads of the second die including first bond pads and second bond pads related to the communication interface, the second bond pads of the second die being redundant bond pads relative to the first bond pads of the second die, and the second programmable connectivity interface coupled between the bond pads of the second die and the circuitry of the second die;
third bond wires coupled between the first terminals of the second substrate and respective bond pads of the first bond pads of the second die; and
fourth bond wires coupled between the second terminals of the second substrate and respective bond pads of the second bond pads of the second die.

20. The apparatus of claim 15, wherein the controller is configured to:
send test data to the IC package;
obtain connectivity test results from the IC package responsive to the test data; and
update the programmable connectivity interface of the controller responsive to the connectivity test results.
